(19) United States
(12) Patent Application Publication
(10) Pub. No.: US 2021/0194202 A1
(43) Pub. Date: Jun. 24, 2021

(54) METROLOGY FOR A BODY OF A GAS DISCHARGE STAGE

(71) Applicant: Cymer, LLC, San Diego, CA (US)

(72) Inventors: Andrei Dorobantu, San Diego, CA (US); Jacob Arthur Cohen, San Diego, CA (US); Kumar Raja Guvindan Raju, San Diego, CA (US); Walter Dale Gillespie, Poway, CA (US); Eric Shaun Gross, Del Mar, CA (US); Richard Carl Ujazdowski, Ramona, CA (US)

(21) Appl. No.: 17/267,949

(22) PCT Filed: Aug. 15, 2019
(86) PCT No.: PCT/US2019/046701

§ 371 Date: Feb. 11, 2021

Related U.S. Application Data
(60) Provisional application No. 62/730,428, filed on Sep. 12, 2018.

(51) Int. Cl. H01S 3/0971; H01S 3/034; H01S 3/101

(52) U.S. Cl. CPC H01S 3/0971; H01S 3/101; H01S 3/034

(57) ABSTRACT

A light source apparatus includes a gas discharge stage including a three-dimensional body defining a cavity that is configured to interact with an energy source, the body including at least two ports that are transmissive to a light beam having a wavelength in the ultraviolet range; a sensor system comprising a plurality of sensors, each sensor is configured to measure a physical aspect of a respective distinct region of the body of the gas discharge stage relative to that sensor; and a control apparatus in communication with the sensor system. The control apparatus is configured to analyze the measured physical aspects from the sensors to thereby determine a position of the body of the gas discharge stage in an XYZ coordinate system defined by an X axis, wherein the X axis is defined by the geometry of the gas discharge stage.

### CROSS REFERENCE TO RELATED APPLICATIONS

This application claims priority to U.S. Application No. 62/730,428, filed Sep. 12, 2018 and titled METROLOGY FOR A BODY OF A GAS DISCHARGE STAGE, which is incorporated herein in its entirety by reference.

### TECHNICAL FIELD

The disclosed subject matter relates to controlling a position or alignment of a body of a gas discharge stage to improve performance of the gas discharge stage.

### BACKGROUND

In semiconductor lithography (or photolithography), the fabrication of an integrated circuit (IC) requires a variety of physical and chemical processes performed on a semiconductor (for example, silicon) substrate (which is also referred to as a wafer). A lithography exposure apparatus (which is also referred to as a scanner) is a machine that applies a desired pattern onto a target region of the substrate. The substrate is fixed to a stage so that the substrate generally extends along an image plane defined by orthogonal X_{L} and Y_{L} directions of the scanner. The substrate is irradiated by a light beam, which has a wavelength in the ultraviolet range, somewhere between visible light and x-rays, and thus has a wavelength between about 10 nanometers (nm) to about 400 nm. Thus, the light beam can have a wavelength in the deep ultraviolet (DUV) range, for example, with a wavelength that can fall from about 100 nm to about 400 nm or a wavelength in the extreme ultraviolet (EUV) range, with a wavelength between about 10 nm and about 100 nm. These wavelength ranges are not exact, and there can be overlap between whether light is considered as being DUV or EUV.

The light beam travels along an axial direction, which corresponds with the Z_{L} direction of the scanner. The Z_{L} direction of the scanner is orthogonal to the image plane (X_{L}-Y_{L}). The light beam is passed through a beam delivery unit, filtered through a reticle (or mask), and then projected onto a prepared substrate. The relative position between the substrate and the light beam is moved in the image plane and the process is repeated at each target region of the substrate. In this way, a chip design is patterned onto a photoresist that is then etched and cleaned, and then the process repeats.

### SUMMARY

In some general aspects, a light source apparatus includes: a gas discharge stage including a three-dimensional body defining a cavity that is configured to interact with an energy source, the body including at least two ports that are transmissive to a light beam having a wavelength in the ultraviolet range; a sensor system comprising a plurality of sensors, each sensor is configured to measure a physical aspect of a respective distinct region of the body of the gas discharge stage relative to that sensor; and a control apparatus in communication with the sensor system. The control apparatus is configured to analyze the measured physical aspects from the sensors to thereby determine a position of the body of the gas discharge stage in an XYZ coordinate system defined by an X axis, wherein the X axis is defined by the geometry of the gas discharge stage.

Implementations can include one or more of the following features. For example, the light source apparatus can also include a measurement system configured to measure one or more performance parameters of a light beam that is generated from the gas discharge stage.

The control apparatus can be in communication with the measurement system. The control apparatus can be configured to: analyze both the position of the body of the gas discharge stage in the XYZ coordinate system and the one or more measured performance parameters of the light beam; and determine whether a modification to the position of the body of the gas discharge stage would improve one or more of the measured performance parameters. The light source apparatus can include an actuation system physically coupled to the body of the gas discharge stage, and configured to adjust a position of the body of the gas discharge stage. The control apparatus can be in communication with the actuation system. The control apparatus can be configured to provide a signal to the actuation system based on the determination regarding whether the position of the body of the gas discharge stage should be modified. The actuation system can include a plurality of actuators, each actuator configured to be in physical communication with a region of the body of the gas discharge stage. Each actuator can include one or more of an electro-mechanical device, a servomechanism, an electrical servomechanism, a hydraulic servomechanism, and/or a pneumatic servomechanism.

The control apparatus can be configured to determine the position of the body of the gas discharge stage in the XYZ coordinate system by determining a translation of the body of the gas discharge stage from the X axis or a rotation of the body of the gas discharge stage from the X axis. The translation of the body of the gas discharge stage from the X axis can include one or more of: a translation of the body of the gas discharge stage along the X axis, a translation of the body of the gas discharge stage along a Y axis that is perpendicular with the X axis, and/or a translation of the body of the gas discharge stage along a Z axis that is perpendicular with the X axis and the Y axis. The rotation of the body of the gas discharge stage from the X axis can include one or more of: a rotation of the body of the gas discharge stage about the X axis, a rotation of the body of the gas discharge stage about a Y axis that is perpendicular with the X axis, and/or a rotation of the body of the gas discharge stage along a Z axis that is perpendicular with the X axis and the Y axis.

Each sensor can be configured to measure as the physical aspect of the body of the gas discharge stage relative to that sensor a distance from the sensor to the body of the gas discharge stage.

The gas discharge stage can include a beam turning device at a first end of the body and a beam coupler at a second end of the body, the beam turning device and the beam coupler intersecting the X axis such that a light beam produced in the gas discharge stage interacts with the beam coupler and the beam turning device. When the body of the gas discharge stage is within a range of acceptable positions, the energy source can supply energy to the cavity of the body, and the beam tuning device and beam coupler can be aligned, the light beam is generated. The light beam can be an amplified light beam having a wavelength in the ultraviolet range. The beam turning device can be an optical module that includes a plurality of optics for selecting and adjusting a wavelength of the light beam and the beam coupler includes a partially reflecting mirror. The beam turning device can include an arrangement of optics that is configured to receive the light beam exiting the body of the gas discharge stage through a first port and changing a direction of the light beam so that the light beam re-enters the body of the gas discharge stage through the first port. The gas discharge stage can also include a beam expander configured to interact with the light beam as it travels between the beam coupler and the cavity.

Each sensor can be configured to be fixedly mounted relative to the body of the gas discharge stage. Each sensor can be configured to be fixed at a distance from the other sensor when it is fixedly mounted relative to the body of the gas discharge stage.

The light source apparatus can also include: a second gas discharge stage that is optically in series with the gas discharge stage and a second plurality of sensors. The second gas discharge stage includes a second three-dimensional body defining a second cavity that is configured to interact with an energy source, the second body including at least two ports that are transmissive to a light beam having a wavelength in the ultraviolet range. Each sensor in the second plurality can be configured to measure a physical aspect of a respective distinct region of the second body relative to that sensor. The control apparatus can be in communication with the second plurality of sensors, and can be configured to analyze the measured physical aspects from the sensors of the second plurality to thereby determine a position of the second body relative to a second XYZ coordinate system defined by a second X axis that passes through the at least two ports of the second body.

Each sensor can include a displacement sensor. The displacement sensor can be an optical displacement sensor, a linear proximity sensor, an electromagnetic sensor, and/or an ultrasonic displacement sensor. Each sensor can include a contact-less sensor.

The X axis can be defined by a beam turning device at a first end of the body and optically coupled with a first port and a beam coupler at a second end of the body and optically coupled with a second port.

In other general aspects, a metrology apparatus includes: a sensor system including a plurality of sensors, each sensor is configured to measure a physical aspect of a body of a gas discharge stage relative to that sensor; a measurement system configured to measure one or more performance parameters of a light beam that is generated from the gas discharge stage; an actuation system including a plurality of actuators, each actuator configured to be physically coupled to a distinct region of the body of the gas discharge stage, the plurality of actuators working together to adjust a position of the body of the gas discharge stage; and a control apparatus in communication with the sensor system, the measurement system, and the actuation system. The control apparatus is configured to: analyze the measured physical aspects from the sensors to thereby determine a position of the body of the gas discharge stage in an XYZ coordinate system defined by an X axis that is defined by the gas discharge stage; analyze the position of the body of the gas discharge stage; analyze the one or more measured performance parameters; and provide a signal to the actuation system to modify the position of the body of the gas discharge stage based on the analyses of the position of the body of the gas discharge stage and the one or more measured performance parameters.

Implementations can include one or more of the following features. For example, the sensors can be positioned apart from each other and relative to the body of the gas discharge stage.

The control apparatus can be configured to provide the signal to the actuation system to modify the position of the body of the gas discharge stage based on the analyses of the position of the body of the gas discharge stage and the one or more measured performance parameters by determining a position of the body of the gas discharge stage that optimizes a plurality of the performance parameters of the light beam.

The X axis can be defined by a beam turning device at a first end of the body and optically coupled with a first port and a beam coupler at a second end of the body and optically coupled with a second port.

In other general aspects, a method includes: measuring, at each of a plurality of distinct regions of a body of a gas discharge stage of a light source, a physical aspect of the body at that region; measuring one or more performance parameters of a light beam that is generated from the gas discharge stage; analyzing the measured physical aspects to thereby determine a position of the body in an XYZ coordinate system defined by an X axis, wherein the X axis is defined by a plurality of apertures associated with the gas discharge stage; analyzing the determined position of the body of the gas discharge stage; analyzing the one or more measured performance parameters; determining whether a modification to the position of the body of the gas discharge stage would improve one or more of the measured performance parameters; and, if it is determined that a modification to the position of the body of the gas discharge stage would improve one or more of the measured performance parameters, then modifying the position of the body of the gas discharge stage.

Implementations can include one or more of the following features. For example, the position of the body of the gas discharge stage can be modified based on the analysis of the determined position of the body of the gas discharge stage.

The position of the body of the gas discharge stage can be determined by determining one or more of a translation of the body of the gas discharge stage from the X axis and/or a rotation of the body of the gas discharge stage from the X axis. The body of the gas discharge stage can be translated from or along the X axis by one or more of: translating the body of the gas discharge stage along the X axis, translating the body of the gas discharge stage along a Y axis that is perpendicular with the X axis, and/or translating the body of the gas discharge stage along a Z axis that is perpendicular with the X axis and the Y axis. The body of the gas discharge stage can be rotated from or about the X axis by one or more of: rotating the body of the gas discharge stage about the X axis, rotating the body of the gas discharge stage about a Y axis that is perpendicular with the X axis, and/or rotating the body of the gas discharge stage along a Z axis that is perpendicular with the X axis and the Y axis.

The physical aspect of the body can be measured by measuring a distance from the sensor to the region of the body of the gas discharge stage.

Determining whether the modification to the position of the body of the gas discharge stage would improve one or more of the measured performance parameters can include determining a position of the body of the gas discharge stage that optimizes a plurality of measured performance parameters.

The method can also include generating the light beam from the gas discharge stage including forming a resonator defined by a beam coupler at one side of the body and a beam turning device at another side of the body, the beam coupler and the beam turning device defining the X axis and generating energy within a gain medium in a cavity defined by the body.

The one or more performance parameters of the light beam can be measured by measuring a plurality of performance parameters. The plurality of performance parameters can be measured by measuring two or more of a repetition rate of a pulsed light beam produced by the light source, an energy of the pulsed light beam, a duty cycle of the pulsed light beam, and/or a spectral feature of the pulsed light beam. The method can also include: determining an optimal position of the body of the gas discharge stage that provides an optimal set of values of the performance parameters of the light beam; and modifying the position of the body of the gas discharge stage to be at the optimal position.

In other general aspects, a metrology kit includes: a sensor system including a plurality of sensors, each sensor is configured to measure a physical aspect of a three-dimensional body relative to that sensor; a measurement system including a plurality of measurement devices, each measurement device configured to measure a performance parameter of a light beam; an actuation system including a plurality of actuators configured to physically couple to the three-dimensional body; and a control apparatus configured to be in communication with the sensor system, the measurement system, and the actuation system. The control apparatus includes: a sensor processing module configured to interface with the sensor system and receive sensor information from the sensor system; a measurement processing module configured to interface with the measurement system and receive measurement information from the measurement system; an actuator processing module configured to interface with the actuation system; and a light source processing module configured to interface with a gas discharge stage having a three-dimensional body.

Implementations can include one or more of the following features. For example, the control apparatus can include an analysis processing module in communication with the sensor processing module, the measurement processing module, the actuator processing module, and the light source processing module. The analysis processing module can be configured to, in use, instruct the light source processing module to adjust one or more characteristics of the gas discharge stage and analyze the sensor information and the measurement information and determine an instruction to the actuator processing module based on the adjusted characteristics of the gas discharge stage.

The metrology kit can be modular such that it is configured to be operably connected and disconnected from one or more gas discharge stages, each gas discharge stage including a respective three-dimensional body defining a cavity that generates a respective light beam.

### DESCRIPTION OF DRAWINGS

FIG. 1 is a block diagram of an apparatus configured to determine a position of a three-dimensional body in an XYZ coordinate system of a gas discharge stage, the apparatus including a sensor system;

FIG. 2A is a perspective view of the apparatus of FIG. 1;

FIG. 2B is a perspective view of the body from the apparatus of FIG. 2A, in which a longitudinal axis of the body is aligned with the X axis of the XYZ coordinate system;

FIG. 3A is a perspective view of the body from the apparatus of FIG. 2A, in which the longitudinal axis of the body is misaligned with the X axis of the XYZ coordinate system by a rotation of the body about a Y axis of the XYZ coordinate system;

FIG. 3B is a perspective view of the body from the apparatus of FIG. 2A, in which the longitudinal axis of the body is misaligned with the X axis of the XYZ coordinate system by a rotation of the body about a Z axis of the XYZ coordinate system;

FIG. 3C is a perspective view of the body from the apparatus of FIG. 2A, in which the longitudinal axis of the body is misaligned with the X axis of the XYZ coordinate system by a rotation of the body about a X axis of the XYZ coordinate system;

FIG. 3D is a perspective view of the body from the apparatus of FIG. 2A, in which the longitudinal axis of the body is misaligned with the X axis of the XYZ coordinate system by a translation of the body along the Y axis of the XYZ coordinate system;

FIG. 3E is a perspective view of the body from the apparatus of FIG. 2A, in which the longitudinal axis of the body is misaligned with the X axis of the XYZ coordinate system by a translation of the body along the Z axis of the XYZ coordinate system;

FIG. 3F is a perspective view of the body from the apparatus of FIG. 2A, in which the longitudinal axis of the body is misaligned with the X axis of the XYZ coordinate system by a translation of the body along the X axis of the XYZ coordinate system;

FIG. 4 is a perspective view of the body and the apparatus of FIGS. 1-2B, showing an implementation of a sensor system and a control apparatus;

FIG. 5 is a side cross-sectional view taken along the YZ plane of the body and apparatus of FIG. 4;

FIG. 6 is a plan view of the XY plane showing the body and an example of how the sensor system of the apparatus of FIGS. 1-2A measures a position of the body;

FIG. 7 is a perspective view of an apparatus configured to measure a position of the body similar to the design of FIG. 2A, except that the apparatus of FIG. 7 further includes an actuation system configured to adjust a position of the body (and therefore also adjust the longitudinal direction of the body) relative to the X axis of the XYZ coordinate system;

FIG. 8 is a perspective view of the body and the apparatus of FIG. 7, showing an implementation of a sensor system, a control apparatus, and an actuation system;

FIG. 9 is a perspective view of an apparatus configured to measure a position of the body and to adjust the position of the body similar to the design of FIG. 7, except that the apparatus of FIG. 9 further includes a measurement system configured to measure or monitor performance or performance characteristics of the gas discharge stage;

FIG. 10 is a perspective view of the body and the apparatus of FIG. 9, showing an implementation of a sensor system, a control apparatus, an actuation system, and a measurement system;

FIG. 11 is a graph of an implementation of an alignment feedback control process in which an optimum energy of a light beam output from the gas discharge stage is determined as the position of the body is rotated about the Z axis and translated along the Y axis;

FIG. 12 is a block diagram of a dual-stage light source including two gas discharge stages, either or both of which can include the apparatus of FIG. 2A, 7, or 9;

FIG. 13 is a block diagram of a metrology kit that includes the components that make up the apparatus of FIG. 9;

FIG. 14 is a flow chart of a procedure performed by the apparatus of FIG. 1, 2A, 7, or 9; and

FIG. 15 is a block diagram of a light source that includes the apparatus of FIG. 1, 2A, 7, or 9.

### DESCRIPTION

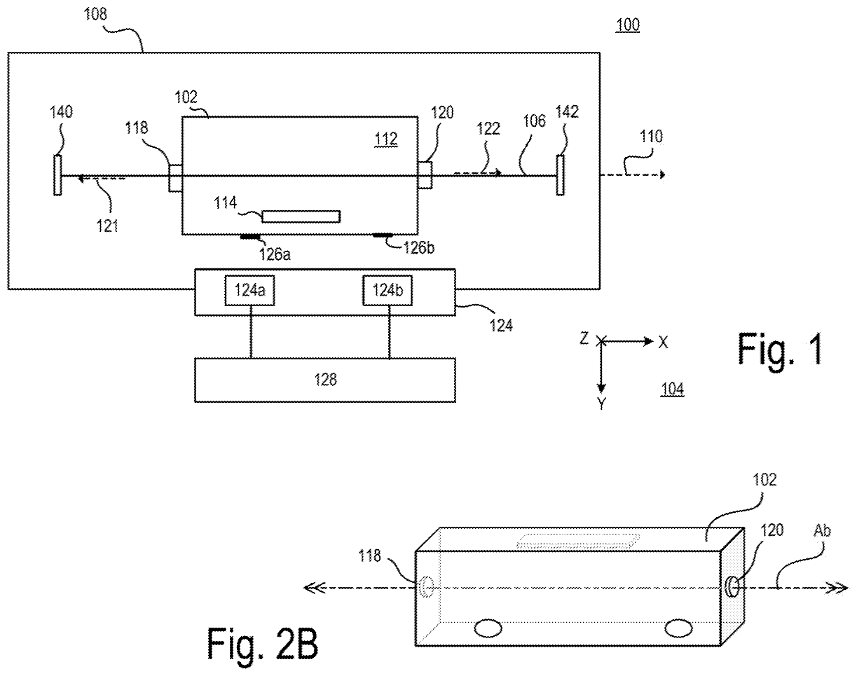

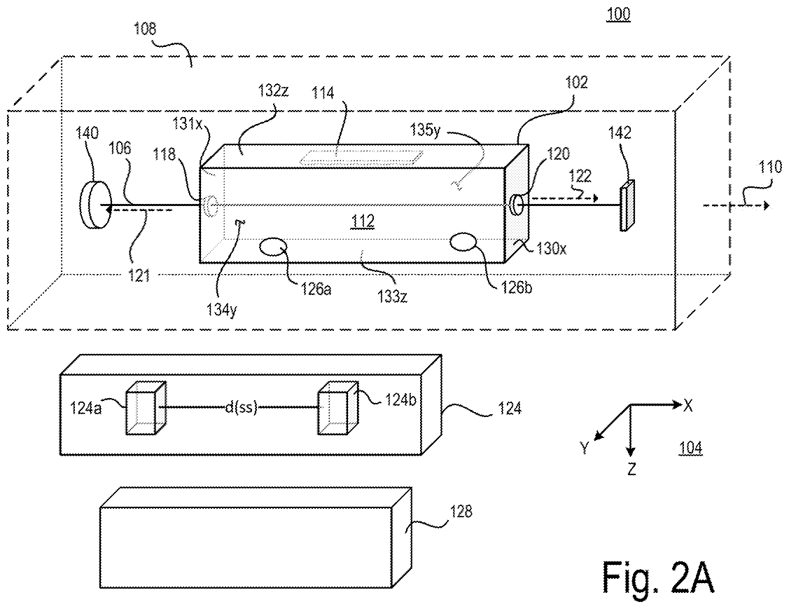

Referring to FIGS. 1 and 2A, an apparatus 100 is designed to determine a position of a three-dimensional body 102 in an XYZ coordinate system 104 relative to an X axis 106 of the coordinate system 104. The body 102 is a part of gas discharge stage 108 that is configured to produce a light beam 110 that has a wavelength in the ultraviolet range. The body 102 defines a cavity 112 that is configured to interact with an energy source 114, which can include a pair of electrodes. The energy source 114 can be fixed to the body 102, as discussed in greater detail below.

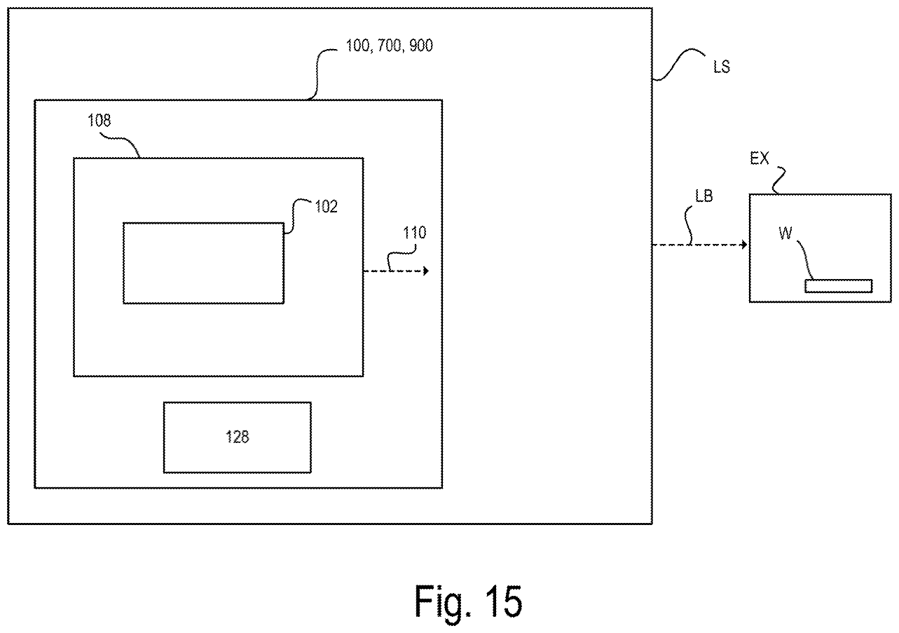

The gas discharge stage 108 includes the body 102 plus other optical components (such as components 140, 142) for producing the light beam 110. The gas discharge stage 108 can include other components not shown in FIGS. 1 and 2A. The representation of the gas discharge stage 108 as a cuboid in FIG. 2A does not necessarily correspond to physical walls and is shown this way to point out that it could include other components not shown. The gas discharge stage 108 can simply correspond to a platform on which all the optical components (including the body 102) are placed. The light beam 110 output from the gas discharge stage 108 can be used in an apparatus such as a lithography exposure apparatus (as discussed below with reference to FIG. 15) for patterning of a substrate W or it can be subjected to further processing before being used in the apparatus.

The body 102 is movable relative to the components of the gas discharge stage 108. During operation, the position of the body 102 in the XYZ coordinate system 104 can change due to factors that are external to the body 102. For example, pressure and temperature variations within the gas discharge stage 108 can cause the body 102 to move in the XYZ coordinate system 104. Another reason for misalignment is an internal change inside the body 102 that leads to a change in the alignment. This can happen, for example, as the electrodes of the energy source 114 age and change shape over the course of their use. Additionally, the wear on the electrodes as well as the geometric modification to the electrodes of the energy source 114 is one reason for having to exchange the body 102 with a new body. Moreover, the body 102 becomes misaligned when it is replaced with a new body 102. In this case, the new body 102 needs to be properly aligned with the X axis 106.

In the example of FIGS. 1 and 2A, the body 102 is aligned with the X axis 106. Alignment between the body 102 and the X axis 106 can be determined based on how well a longitudinal axis Ab of the body 102 is aligned with the X axis 106. The longitudinal axis Ab of the body 102 is shown in FIG. 2B. This longitudinal axis Ab can be defined as that axis that intersects two ports 118, 120 at ends of the body 102. The ports 118, 120 are transmissive to a light beam 122 (that will form the light beam 110) having a wavelength in the ultraviolet range.

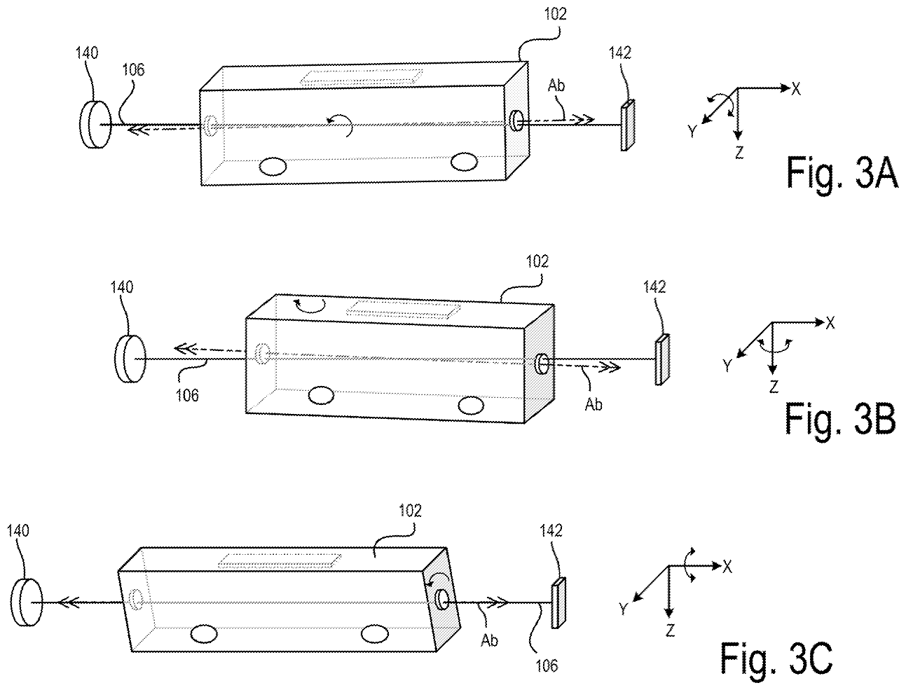

Referring to FIGS. 3A-3F, the body 102 of the gas discharge stage 108 can be misaligned relative to the X axis 106 in one or more manners. For example, in FIG. 3A, the body 102 is rotated out of alignment about the Y axis and its longitudinal axis Ab is not aligned with the X axis 106. In FIG. 3B, the body 102 is rotated out of alignment about the Z axis and its longitudinal axis Ab is not aligned with the X axis 106. And, in FIG. 3C, the body 102 is rotated out of alignment about the X axis. In this case, the longitudinal axis Ab is shifted along the X axis 106. If the body 102 is configured to rest on a platform, then it is being held up by gravity and the plane of the earth is the XY plane. In this situation, a common misalignment is that shown in FIG. 3B in which the body 102 is rotated out of alignment about the Z axis.

In FIG. 3D, the body 102 is translated out of alignment along the Y axis, and the longitudinal axis Ab is shifted from the X axis 106 along the Y axis. In FIG. 3E, the body 102 is translated out of alignment along the Z axis, and the longitudinal axis Ab is shifted from the X axis 106 along the Z axis. And in FIG. 3F, the body 102 is translated out of alignment along the X axis 106, and the longitudinal axis Ab is shifted along the X axis 106. If the body 102 is configured to rest on the platform, and is being held up by gravity and the plane of the earth is the XY plane, then a common misalignment that has a relatively larger impact on efficiency of the gas discharge stage 108 is that shown in FIG. 3D in which the body 102 is translated along the Y axis.

It is possible for the body 102 to be misaligned in more than one way, and thus it could be both translated and rotated, translated along more than one axes, or rotated about more than one axes.

Certain misalignments to the body 102 can have a different impact on the efficiency and operation of the gas discharge stage 108. Moreover, some adjustments may be more accessible or feasible to modify. For example, translation along the Y axis (shown in FIG. 3D) and rotation about the Z axis (shown in FIG. 3B) can be performed relatively easily and thus, their impact on the efficiency and operation of the gas discharge stage 108 can be tracked. Thus, in this example, the apparatus 100 determines a translation of the body 102 along the Y axis and determines a rotational value (angle) of the body 102 about the Z axis. It is possible for the apparatus 100 to determine a translation of the body 102 along either or both of the other two axes and a rotational value about either or both of the other two axes.

The position of the body 102 or misalignment of the body 102 relative to the X axis 106 has an impact on the efficiency at which the gas discharge stage 108 operates. If the body 102 is misaligned relative to the X axis 106, this can lead to inefficiency in the operation of the gas discharge stage 108, and this can result in reduced quality in the light beam 110. For example, the path of the light beam 110 coincides with the X axis 106, and the X axis 106 is determined based on apertures associated with optical components 140, 142. The energy source 114 (which includes the electrodes) that is fixed to the body 102 supplies the energy to the cavity 112 to pump the gas with an electric discharge. The pumping of the gas with the energy source 114 produces a plasma state of the gas. Moreover, when this plasma state aligns with the X axis 106 (which occurs when the body 102 is properly aligned with the X axis 106), there is efficient coupling between the resonator cavity (which is formed by the components 140, 142 and defined along the X axis 106) and the plasma state, and the light beam 110 parameters are improved. On the other hand, when this plasma state is misaligned from the X axis 106 (which occurs when the body 102 is misaligned from the X axis 106), there is inefficient coupling between the resonator cavity and the plasma state, and the light beam 110 parameters suffer. For example, the efficiency of operation of the gas discharge stage 108 drops. In this scenario, then more energy is needed to supply to the body 102 (for example, by way of an energy source 114) in order to maintain performance parameters of the light beam 110.

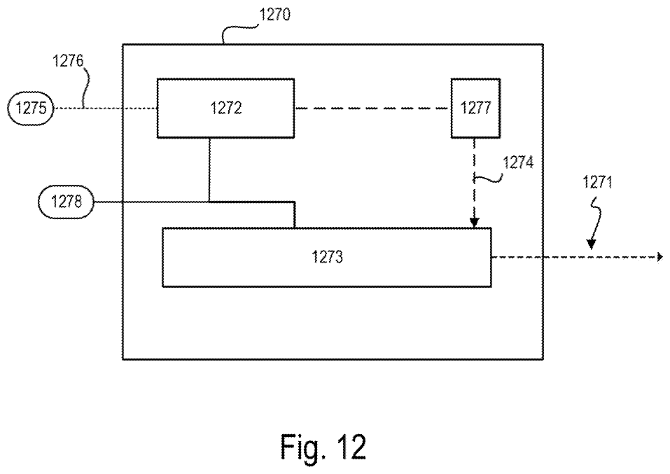

As another example, in a dual-stage design that is discussed below with respect to FIG. 12, misalignment of the body 102 in a first gas discharge stage 1272 results in lower efficiency of that first gas discharge stage 1272, which leads to a reduced performance in a second gas discharge stage 1273 that receives the light beam 1273 output from the first gas discharge stage 1272. This, in turn, causes the operation of the second gas discharge stage 1273 to suffer unless changes are made to operate the second gas discharge stage 1273.

The apparatus 100 provides a quantifiable metrology for this alignment, as well as a fast and accurate direct measure of the position of the body 102 relative to the X axis 106 not previously provided. Moreover, the apparatus 100 determines the position of the body 102 relative to the X axis 106 without having to rely on slow and inaccurate measures of the performance of the gas discharge stage 108.

In particular, the apparatus 100 determines the position of the body 102 relative to the XYZ coordinate system 104 using a plurality of direct measurements of the body 102, as discussed next.

In some implementations, the apparatus 100 can operate to determine the position of the body 102 during use of the gas discharge stage 108 in which the light beam 110 is being produced. In other implementations, the apparatus 100 can operate to determine the position of the body 102 after the body 102 is initially installed in the system, but before it is used to produce the light beam 110 for use by the apparatus.

The apparatus 100 includes a sensor system 124, the output of which is used to determine the position of the body 102 relative to the X axis 106. The sensor system 124 includes at least two sensors 124a and 124b that provide for the direction measurements of the body 102. While two sensors 124a and 124b are shown in FIG. 1, it is possible for the sensor system 124 to have more than two sensors. Each sensor 124a, 124b is configured to measure a physical aspect of a respective distinct region 126a, 126b of the body 102 of the gas discharge stage 108 relative to that sensor 124a, 124b.

The apparatus 100 includes a control apparatus 128 in communication with each of the sensors 124a, 124b of the sensor system 124. The control apparatus 128 is configured to analyze the measured physical aspects from the sensors 124a, 124b to thereby determine a position of the body 102 of the gas discharge stage 108 relative to the X axis 106.

The body 102 can be any shape configured to house, within the cavity 112, a gas mixture that includes a gain medium. Optical amplification occurs in the gain medium when enough energy is provided by the energy source 114 to form the plasma state. The gas mixture can be any suitable gas mixture configured to produce an amplified light beam (or laser beam) around the required wavelengths and bandwidth. For example, the gas mixture can include argon fluoride (ArF), which emits light at a wavelength of about 193 nm, or krypton fluoride (KrF), which emits light at a wavelength of about 248 nm.

Moreover, an optical feedback mechanism can be arranged or configured relative to the body 102 to provide an optical resonator, as discussed in detail below.

The energy source 114 can include two elongated electrodes that extend in the cavity 112 and are fixed to the body 102. Current supplied to the electrodes causes an electromagnetic field to generate within the cavity 112, the electromagnetic field providing the energy needed to the gain medium to form the plasma state in which optical amplification occurs. The body 102 can also house a fan that circulates the gas mixture between the electrodes.

The body 102 is made of a rigid and non-reactive material such as a metal alloy (stainless steel). The body 102 can be of any suitable geometry, and the geometry is determined by the arrangement of the electrodes as well as the ports 118, 120. The body 102 can have a cuboid shape or a cube shape. As shown in FIG. 2A, the body 102 has a cuboid shape with two flat parallel surfaces 130x, 131x that are intersected by the X axis 106 and four flat surfaces 132z, 133z, 134y, 135y extending between the flat surfaces 130x, 131x. The surfaces 132z, 133z are parallel with each other and are intersected by the Z axis and the surfaces 134y, 135y are parallel with each other and are intersected by the Y axis. In this example, the regions 126a, 126b are on the surface 134y. In other implementations, the regions 126a, 126b could be on other surfaces or several different surfaces of the body 102.

The ports 118, 120 on the body 102 are transmissive to the light beam 122 that forms the light beam 110. Thus, the ports 118, 120 are transmissive to light having a wavelength in the ultraviolet range. The ports 118, 120 can be made of a rigid substrate such as fused silica or calcium fluoride that can be coated with anti-reflective material. The ports 118, 120 can have flat surfaces that interact with the light beam 122. Because the cavity 112 of the body 102 holds or retains the gas mixture, the body 102 needs to be enclosed or sealed, and it can be hermetically sealed. Thus, the ports 118, 120 are also hermetically sealed in respective openings of the body 102 to ensure that gas mixture does not leak out of the body 102 at the seam between a port and the body 102.

In some implementations, the X axis 106 and the XYZ coordinate system 104 are defined by the design of the gas discharge stage 108. In particular, the X axis 106 is defined as that line that passes through two apertures within the gas discharge stage 108. These two apertures can be positioned adjacent respective optical components 140, 142 that interact with the body 102 in the gas discharge stage 108. In this way, the optical components 140, 142 and their apertures define the X axis 106 (and therefore the XYZ coordinate system 104). Moreover, these optical components 140, 142 define the optical resonator for forming the light beam 110.

In some implementations, the optical components 140, 142 can form the optical feedback mechanism to provide an optical resonator and thereby output the light beam 110 from the light beam 122. Thus, when the body 102 of the gas discharge stage 108 is within a range of acceptable positions, the energy source 114 supplies energy to the cavity 112 of the body 102, and the optical components 140, 142 are aligned, the light beam 122 is generated.

In some implementations, the optical component 140 can be a spectral feature apparatus that receives a pre-cursor light beam 121 and enables fine tuning of spectral features of the light beam 122 by adjusting the spectral features of the pre-cursor light beam 121. Spectral features that can be tuned using a spectral feature apparatus include the center wavelength and the bandwidth of the light beam 122. The spectral feature apparatus includes a set of optical features or components arranged to optically interact with the pre-cursor light beam 121. The optical components of the spectral feature apparatus include, for example, a dispersive optical element, which can be a grating, and a beam expander made of a set of refractive optical elements, which can be prisms. The optical component 142 can be an output coupler that allows the extraction of the light beam 122 from the intracavity beam. The output coupler can include a partially reflective mirror, allowing a certain portion of the intracavity beam to transmit through as the light beam 122. The gas discharge stage 108 can also include a beam expander configured to interact with the light beam 122 as it travels between the output coupler (the optical component 142) and the cavity 112.

In other implementations, the optical component 140 can be beam turning device and the optical component 142 can be a beam coupler. The beam turning device includes an arrangement of optics that is configured to receive the pre-cursor light beam 121 exiting the body 102 of the gas discharge stage 108 through the port 118 and changing a direction of the light beam 121 so that the light beam 121 re-enters the body of the gas discharge stage through the first port 118.

As discussed above, each sensor 124a, 124b in the sensor system 124 is configured to measure a physical aspect of the body 102 of the gas discharge stage 108 relative to that sensor 124a, 124b. Each sensor 124a, 124b can measure, as the physical aspect of the body 102, a distance from the sensor 124a, 124b to the body 102 of the gas discharge stage 108.

In various implementations, the sensors 124a, 124b are mounted to a mechanically stable structure of the gas discharge stage 108, where the structure holds the sensors 124a, 124b in fixed positions relative to each other and to components that define the X axis 106, or that define the XYZ coordinate system 104. For example, the sensors 124a, 124b can be mounted on an optical table or on to other stable mechanical mounts that are rigidly coupled to optical elements (for example, optical elements 140, 142) that delineate the X axis 106, which is the optical axis of the system.

For example, each sensor 124a, 124b is configured to be fixedly mounted relative to XYZ coordinate system 104. Thus, during measurements, the sensors 124a, 124b are fixed relative to the XYZ coordinate system 104. Additionally, each sensor 124a, 124b is configured to be fixed at a distance from the other sensor 124b, 124a when it is fixedly mounted relative to the XYZ coordinate system 104. Thus, the distance d(ss) between the sensors 124a, 124b is fixed during operation and measurements. The distance d(ss) between the sensors 124a, 124b is great enough along the X axis 106 so that it is possible for the control apparatus 128 to determine a rotation about the Z axis (FIG. 3B) based on the output from the sensors 124a, 124b. In particular, relative changes between the output from each of the sensors 124a, 124b can be used to determine the rotation about the Z axis (FIG. 3B). The sensors 124a, 124b have a measurement resolution that is fast enough for enabling alignment. For example, a temporal resolution of 1 second (s) can be fast enough; or a temporal resolution less than 1 s (for example, 0.1 s) can be fast enough.

In some implementations, each sensor 124a, 124b includes a displacement sensor. The displacement sensor can be an optical displacement sensor, a linear proximity sensor, an electromagnetic sensor, or an ultrasonic displacement sensor.

Each sensor 124a, 124b can be a contact-less sensor, which means that it does not make contact with the body 102. In such a design in which the sensor 124a, 124b is contact-less, the measurement itself does not noticeably (for example, greater than 1μ) displace the body 102, because any such displacement could impact the performance of the gas discharge stage 108.

Any contact-less metrology with a suitable resolution (for example, a resolution that is better than 10 μm (that is, less than 10 μm)) is suitable for this application. One example of a contact-less sensor is a laser displacement sensor, which is an off-the-shelf product that includes a laser light source and a photodiode array. The laser light source of each sensor 124a, 124b shines light on the surface 134y of the body 102; the light is reflected back toward the respective sensor 124a, 124b; and the location on the diode array at which the reflected light lands corresponds to a displacement of surface 134y of the body 102.

In other implementations, the sensors 124a, 124b are contact sensors, which come into minimal contact with the body 102 at the respective regions 126a, 126b. For example, the sensors can be electromechanical devices used to convert mechanical motion of the body 102 into a variable electrical current, voltage, or electric signals. An example of such a sensor is a linear variable displacement transducer (LVDT), which is a device that provides a voltage output quantity related to the characteristic (position) being measured.

The control apparatus 128 includes one or more of digital electronic circuitry, computer hardware, firmware, and software. The control apparatus 128 includes memory, which can be read-only memory and/or random-access memory. Storage devices suitable for tangibly embodying computer program instructions and data include all forms of non-volatile memory, including, by way of example, semiconductor memory devices, such as EPROM, EEPROM, and flash memory devices; magnetic disks such as internal hard disks and removable disks; magneto-optical disks; and CD-ROM disks. The control apparatus 128 can also include one or more input devices (such as a keyboard, touch screen, microphone, mouse, hand-held input device, etc.) and one or more output devices (such as a speaker or a monitor).

The control apparatus 128 includes one or more programmable processors, and one or more computer program products tangibly embodied in a machine-readable storage device for execution by a programmable processor. The one or more programmable processors can each execute a program of instructions to perform desired functions by operating on input data and generating appropriate output. Generally, the processor receives instructions and data from memory. Any of the foregoing may be supplemented by, or incorporated in, specially designed ASICs (application-specific integrated circuits).

The control apparatus 128 includes a set of modules, with each module including a set of computer program products executed by one or more processors such as the processors. Moreover, any of the modules can access data stored within the memory. Each module can receive data from other components and then analyze such data as needed. Each module can be in communication with one or more other modules.

Although the control apparatus 128 is represented as a box (in which all of its components can be co-located), it is possible for the control apparatus 128 to be made up of components that are physically remote from each other. For example, a particular module can be physically co-located with the sensor system 124 or a particular module can be physically co-located with another component.

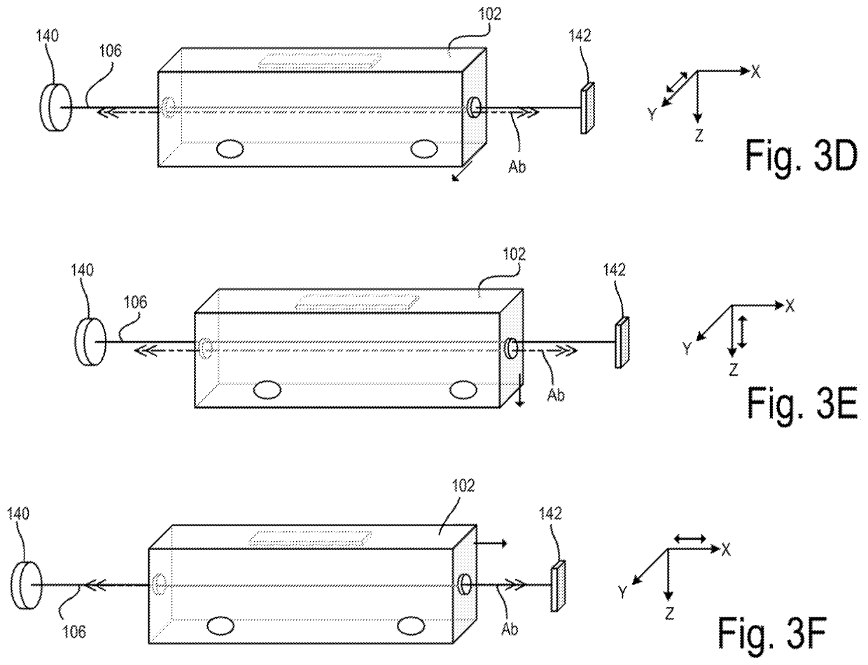

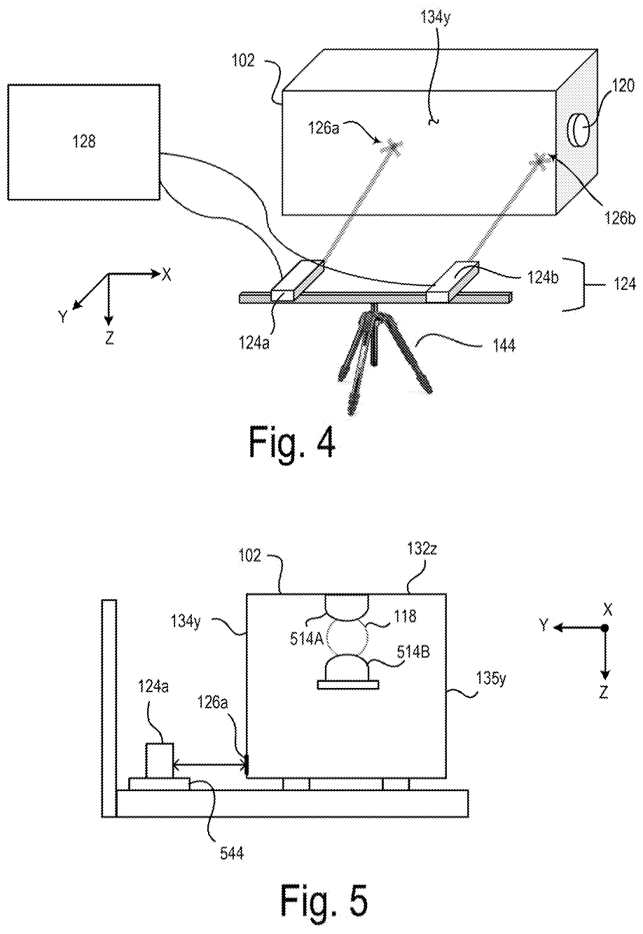

Referring to FIG. 4, in some implementations, the sensors 124a, 124b are arranged to interact with the surface 134y. In these implementations, the sensors 124a, 124b are mounted on a platform 144, which supports the weight of and maintains the stability of the sensors 124a, 124b. In FIG. 4, the platform 144 is a three-legged frame or stand. FIG. 5 shows a side cross-sectional view of the arrangement. In FIG. 5, the platform 144 is a basic platform base 544 on which the sensors 124a, 124b are placed. The platform base 544 can be integrated into a frame or other component fixed within the gas discharge stage 108. The sensors 124a, 124b can be repositionable; that is, the sensors 124a, 124b can be placed at any location relative to any two regions of the body 102 and then moved to another location relative to two other regions of the body 102.

As shown in FIG. 5, the energy source 114 is a pair of electrodes 514A, 514B arranged in the cavity 112. The electrodes 514A, 514B extend along the X axis 106.

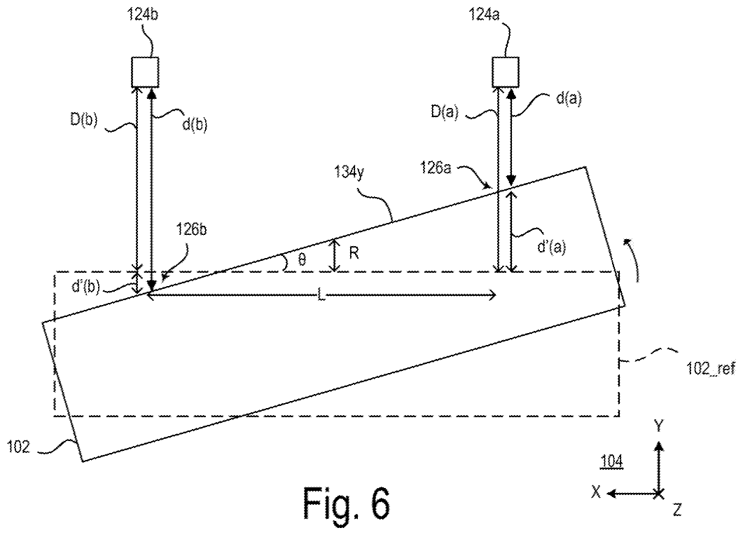

Referring also to FIG. 6, each sensor 124a, 124b measures a distance or displacement from the respective region 126a, 126b of the surface 134y of the body 102. For example, the sensor 124a measures a displacement d(a) from the sensor 124a to the region 126a of the surface 134y and the sensor 124b measures a displacement d(b) from the sensor 124b to the region 126b of the surface 134y. Additionally, the calculation performed by the control apparatus 128 requires a set of reference displacements, D(a) and D(b). The reference displacements D(a) and D(b) are measurements taken by respective sensors 124a, 124b during a time when the body 102 is properly aligned with the X axis 106 and the XYZ coordinate system 104 (this is shown by the dashed line box labeled as 102_ref. In some implementations, proper alignment between the body 102 and the X axis 106 can be assumed to occur when the gas discharge stage 108 is operating at its highest efficiency (for example, when the most energy input by way of the energy source 114 is converted into an energy in the light beam 110).

The values of the displacement d(a) and d(b) output from the respective sensors 124a, 124b are not necessarily linearly independent of each other. This means that the displacement of one, such as d(a), can be written in terms of the other, such as d(b). It is possible to transform such linearly dependent values into linearly independent values with the use of additional information. In this case, the distance L taken along the X axis 106 between the regions 126a, 126b when the body 102 is aligned with the X axis 106 can be used to provide this transformation. Specifically, the distance L, along with d(a), and d(b) can be used to determine the relative position of the center of the body 102 (given by R) and the relative angular orientation θ of the body about the Z axis, as discussed next.

The relative displacements d′(a) and d′(b) are given by:

d′(a)=D(a)−d(a); and

d′(b)=D(b)−d(b).

And, the relative displacement R of the body 102 is defined as half the sum of the relative displacements d′(a) and d′(b), as follows:

$$R = \frac{{d}^{′} ( a ) + {d}^{′} ( b )}{2} .$$

The relative angular orientation θ can be approximated as a ratio of the difference between the relative displacements d′(a) and d′(b) and the distance L, as follows:

$$θ ∼ \frac{{d}^{′} ( a ) - {d}^{′} ( b )}{L} .$$

The small angle approximation is invoked because L>>|d′(a)−d′(b)|. For example, L is on the order of hundreds of millimeters (mm) (for example, 0.5-0.7 meters) while |d′(a)−d′(b)| is on the order of a mm.

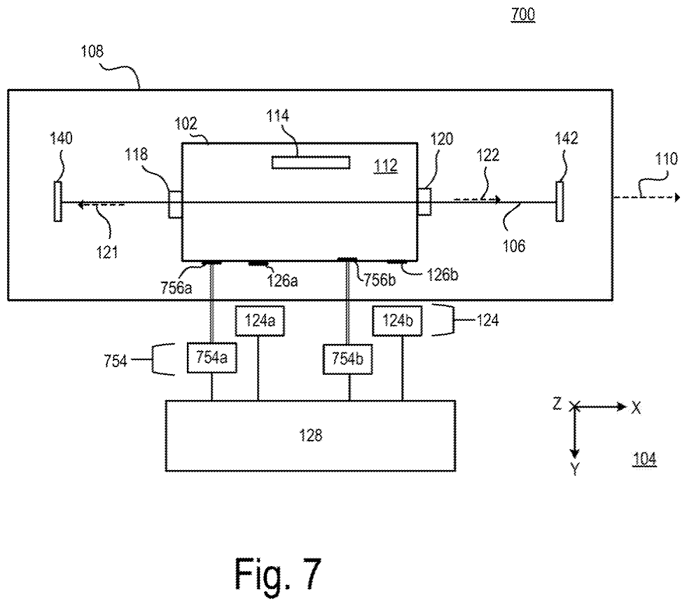

Referring to FIG. 7, in some implementations, an apparatus 700 is designed to not only determine the position of the three-dimensional body 102, but also to move the body 102 in the XYZ coordinate system 104. To this end, the apparatus 700 is substantially similar to the apparatus 100, and includes all of the components detailed above and shown in FIG. 1 and a discussion of those components is not repeated here.

The apparatus 700 further includes an actuation system 754 physically coupled to the body 102 of the gas discharge stage 108, the actuation system 754 being configured to adjust a position of the body 102 of the gas discharge stage 108 within the XYZ coordinate system 104. The control apparatus 128 is in communication with the actuation system 754 and is configured to provide a signal to the actuation system 754 based on the output from the sensor system 124. In particular, the control apparatus 128 determines whether the position of the body 102 of the gas discharge stage 108 should be modified based on the output from the sensor system 124 and the control apparatus 128 determines how to adjust one or more signals to the actuation system 754 based on this determination.

The actuation system 754 includes a plurality of actuators 754a, 754b, etc., with each actuator configured to be in physical communication with a respective region 756a, 756b, etc. of the body 102 of the gas discharge stage 108. While the actuation system 754 is shown as being in physical communication with the surface 134y, it is possible for the actuation system 754 to include one or more actuators that are in physical communication with one or more other surfaces of the body 102. Moreover, it is not necessary for the actuation system 754 to be in physical communication with the same surface or surfaces that are measured by the sensor system 124.

Each actuator 754a, 754b can include one or more of an electro-mechanical device, a servomechanism, an electrical servomechanism, a hydraulic servomechanism, and/or a pneumatic servomechanism. The various motions imparted to the regions 756a, 756b are used to adjust the position of the body 102 along any of the rotational directions detailed above with respect to FIGS. 3A-3C and any of the translational directions detailed above with respect to FIGS. 3D-3F.

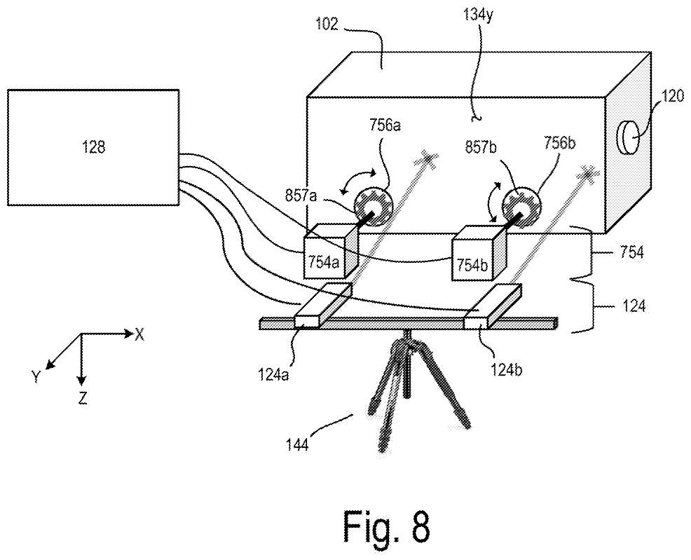

Referring to FIG. 8, in some implementations, each respective region 756a, 756b is associated with a rotational mount 857a, 857b attached to the surface 134y. The rotational mount 857a, 857b is actuated by rotation, and the rotation is converted into a translational motion. Thus, for example, rotation of the mount 857a in a clockwise direction translates a rod that is fixed to the region 756a along the −Y direction (which causes the region 756a to translate along the −Y direction). And, while rotation of the mount 857a in a counterclockwise direction translates the rod that is fixed to the region 756a along the Y direction (which causes the region 756a to translate along the Y direction). By rotating both rotational mounts 857a, 857b at the same time and synchronously (in the same direction), the body 102 is translated along the Y axis, as shown in FIG. 3D. Rotation of the mounts 857a, 857b at the same time and asynchronously (in opposite directions) causes the body 102 to be rotated about the Z axis, as shown in FIG. 3B. For example, rotating one mount 857a clockwise while rotating the other mount 857b counterclockwise causes the region 756a to be translated along the −Y direction and the region 756b to be translated along the Y direction and this causes the rotation of the body 102 about the Z axis. It is possible to do both a synchronous and an asynchronous rotation of the mounts 857a, 857b to impart both a translation along the Y axis and a rotation about the Z axis to the body 102. In this example, the rotational mount 857a, 857b at the respective region 756a, 756b is controlled, respectively, by the actuator 754a, 754b. The actuator 754a, 754b can be any device that rotates the mount respective mount 857a, 857b. Moreover, the rotation of the mount 857a, 857b can be in incremental steps.

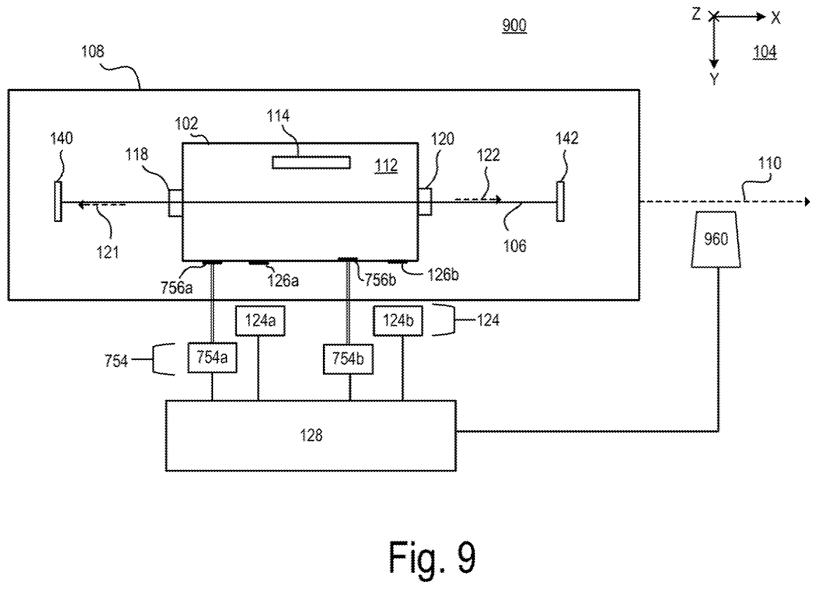

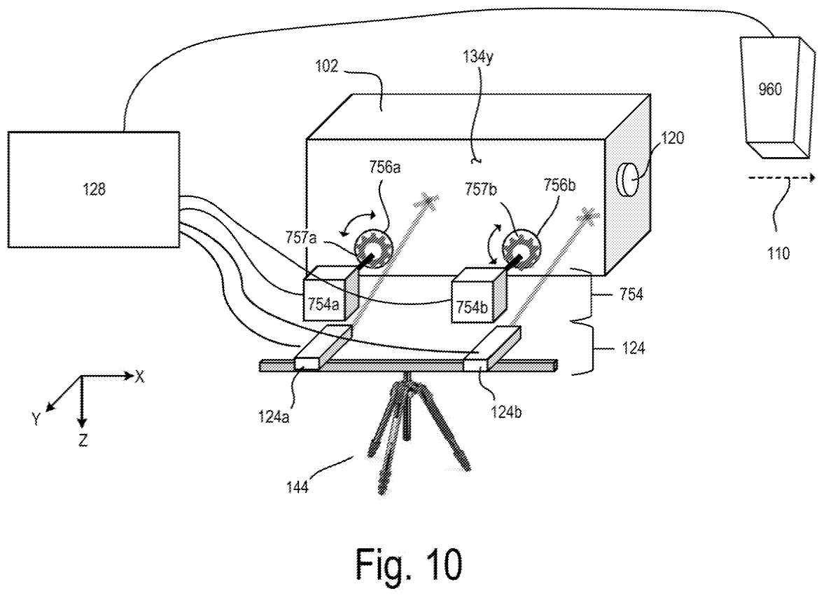

Referring to FIG. 9, in some implementations, an apparatus 900 is designed to not only determine the position of the three-dimensional body 102 (using the sensor system 124), and to adjust a position of the body 102 (using the actuation system 754), but also to measure or monitor performance or performance characteristics of the gas discharge stage 108. As discussed above, the alignment of the body 102 impacts or changes the performance of the gas discharge stage 108, and thus, it is expected that the misalignment of the body 102 will reduce the performance. To this end, the apparatus 900 is substantially similar to the apparatus 700, and includes all of the components detailed above and shown in FIG. 1 and a discussion of those components is not repeated here.

The apparatus 900 further includes a measurement system 960 arranged to measure performance parameters of the light beam 110. Examples of performance parameters include energy E of the light beam 110, a spectral feature such as bandwidth or wavelength of the light beam 110, and a dose of the light beam 110 at the apparatus (such as the lithography exposure apparatus). The control apparatus 128 is in communication with the measurement system 960. In this way, the control apparatus 128 can find the best or improved position or alignment of the body 102 that provides the best or improved performance parameter or parameters. Because the performance of the gas discharge stage 108 is measured based on many different parameters, a parameter space that includes a plurality of parameters can be considered by the control apparatus 128 in making the determination. For example, the control apparatus 128 could perform an adaptive control for adjusting the position of the body 102 that provides a set of performance parameters of the light beam 110 that fall within acceptable ranges.

The measurement system 960 can include one or more measurement devices, with each measurement device positioned relative to the light beam 110 and to measure a specific performance parameter. The measurement system 960 can include as measurement device, an energy monitor for measuring the energy of the light beam 110. The measurement system 960 can include as a measurement device, a spectral feature analysis device configured to measure the spectral feature (bandwidth or wavelength) of the light beam 110. In these cases, the measurement devices can be devices that are already included in the gas discharge stage 108 or are a part of an analysis module that is already present to measures these aspects of the light beam 110. For example, an analysis module can include a wavemeter and a bandwidth meter that includes, among other components, an etalon with an imaging lens, as well as beam homogenization optics. The analysis module can also include a photodetector module (PDM) that monitors the energy of the light beam 110, and provides a fast photodiode signal for diagnostic and timing purposes. In some implementation, one or more energy sensors can be placed anywhere along the path of the light beam 110. The control apparatus 128 can estimate an efficiency of the gas discharge stage 108 based on a ratio of this measured energy to an energy input through the energy source 114 (which can be a voltage applied to the electrodes of the energy source 114).

The measurement devices can be associated with diagnostics within a spectral feature adjuster (such as spectral feature adjuster 1275 shown in FIG. 12). The spectral feature adjuster 1275 receives a pre-cursor light beam 1276 from body 102 of the gas discharge stage 1272 to enable fine tuning of spectral parameters such as the center wavelength and the bandwidth of the light beam 1274 at relatively low output pulse energies. It is possible to monitor the beam expansion optics within the spectral feature adjuster 1272 to track the spectral feature (such as the bandwidth) of the light beam 110 because the beam expansion within the spectral feature adjuster 1275 directly correlates to the bandwidth of the light beam 1274 (and therefore the light beam 110).

The measurement system 960 can include a measurement device configured to measure the dose of the light beam 110 at the lithography exposure apparatus. The measurement system 960 can include a measurement device configured to measure the repetition rate at which the pulses of the light beam 110 are produced. The measurement system 960 can include a measurement device configured to measure the duty cycle of the light beam 110. These measurement devices can include a laser energy detector (such as a photodetector). In this example, the dose can be estimated as the sum of the energy over a fixed number of pulses detected by the laser energy detector; the repetition rate can be estimated as an inverse of the time between any two pulses (usually fixed) detected by the laser energy detector; and the duty cycle can be arbitrarily defined as the number of pulses fired in a time frame (such as the most recent two minutes) divided by a maximum repetition rate times the time that passed in the time frame (for example, two minutes). The measurement devices can also include a timer in order for the control apparatus 128 to compute the repetition rate and the duty cycle from the output.

The control apparatus 128 can send independent signals to actuators 754a, 754b, read independent measurements from each of the sensors 124a, 124b, and read independent measurements from each of the measurement devices in the measurement system 960.

In operation, the control apparatus 128 analyzes both the position of the body 102 of the gas discharge stage 108 (it receives from the sensor system 124) and the one or more measured performance parameters of the light beam 110 (it receives from the measurement system 960. The control apparatus 128 determines whether a modification to the position of the body 102 of the gas discharge stage 108 would improve one or more of the measured performance parameters. The control apparatus 128 can perform a process that maps the position space and determines an optimal position that achieves the best performance parameter (or parameters).

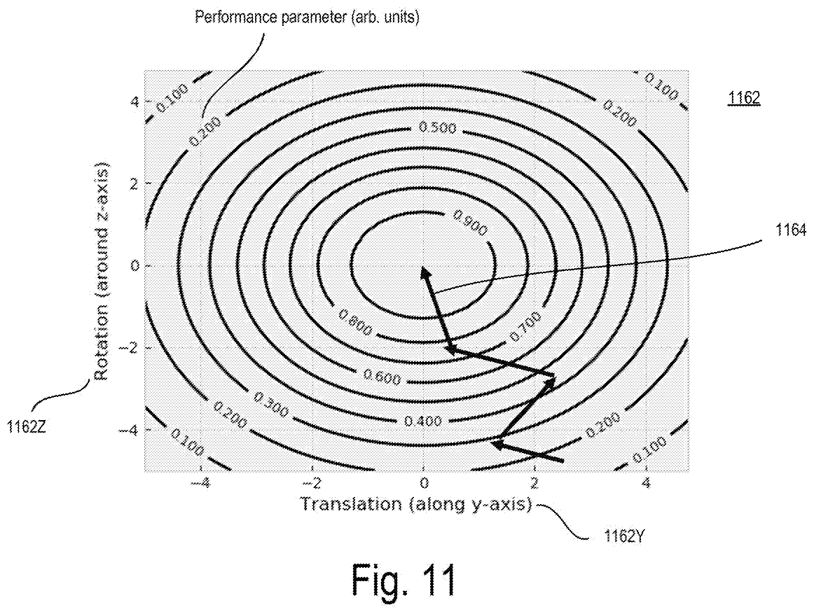

Referring to FIG. 11, an example of an alignment feedback control process is shown in a topographic map 1162 in which the position of the body 102 can be rotated about the Z axis (FIG. 3B), translated along the Y axis (FIG. 3D), or both. The map 1162 shows a value of a performance parameter (such as energy) relative to values of the rotation about the Z axis (1162Z) and values of the translation along the Y axis (1162Y). Because the map is a topographic map, the value of the energy is listed on each line. The shape of the three dimensional surface that corresponds to the map 1162 is depicted by these contour lines, and the relative spacing of the lines indicating the relative slope of the three dimensional surface.

In this example, the control apparatus 128 receives positions measured by sensors 124a, 124b while controlling the actuators 754a, 754b, in order to generate the map 1162 of the energy of the light beam 110. Higher values of the energy represent more efficient energy values. Thus, a value of the position of the body 102 along the Y axis and a rotational angle of the body 102 about the Z axis is determined that provides the most efficient energy value of the light beam 110. In some implementations, the feedback control process can be configured to intelligently find the peak of the map (and therefore the peak of the energy) without mapping the entire space. For example, the search path 1164 shows one specific way to modify the position of the body 102 along the Y axis and to rotate the body 102 about the Z axis to obtain the most efficient energy value of the light beam 110.

The feedback control process can be a non-linear optimization problem that finds the best solution (the peak of the map or peak of the energy) from all feasible solutions. For example, the process can be a gradient ascent, which is a first-order iterative optimization algorithm for finding the maximum of a function.

Referring to FIG. 12, in some implementations, the gas discharge stage 108 can be incorporated into a dual-stage light source 1270. The light source 1270 is designed as a pulsed light source that produces an amplified light beam 1271 of optical pulses. The light source 1270 includes a first gas discharge stage 1272 and a second gas discharge stage 1273. The second gas discharge stage 1273 is optically in series with the first gas discharge stage 1272. In general, the first stage 1272 includes a first gas discharge chamber housing an energy source and containing a gas mixture that includes a first gain medium. The second gas discharge stage 1273 includes a second gas discharge chamber housing an energy source and containing a gas mixture that includes a second gain medium.

The first stage 1272 includes a master oscillator (MO) and the second stage 1273 includes a power amplifier (PA). The MO provides a seed light beam 1274 to the PA. The master oscillator typically includes a gain medium in which amplification occurs and an optical feedback mechanism such as an optical resonator. The power amplifier typically includes a gain medium in which amplification occurs when seeded with the seed light beam 1274 from the master oscillator. If the power amplifier is designed as a regenerative ring resonator then it is described as a power ring amplifier (PRA) and in this case, enough optical feedback can be provided from the ring design.

A spectral feature adjuster 1275 receives a pre-cursor light beam 1276 from the master oscillator of the first stage 1272 to enable fine tuning of spectral parameters such as the center wavelength and the bandwidth of the light beam 1274 at relatively low output pulse energies. The power amplifier receives the light beam 1274 from the master oscillator and amplifies this output to attain the necessary power for output to use in photolithography by the lithography exposure apparatus.

The master oscillator includes a discharge chamber having two elongated electrodes, a laser gas that serves as the gain medium, and a fan circulating the gas between the electrodes. A laser resonator is formed between the spectral feature adjuster 1275 on one side of the discharge chamber, and an output coupler 1277 on a second side of the discharge chamber to output the seed light beam 1274 to the power amplifier.

The power amplifier includes a power amplifier discharge chamber, and if it is a regenerative ring amplifier, the power amplifier also includes a beam reflector or beam turning device that reflects the light beam back into the discharge chamber to form a circulating path. The power amplifier discharge chamber includes a pair of elongated electrodes, a laser gas that serves as the gain medium, and a fan for circulating the gas between the electrodes. The seed light beam 1274 is amplified by repeatedly passing through the power amplifier. The second stage 1273 can include a beam modification optical system that provides both a way (for example, a partially-reflecting mirror) to in-couple the seed light beam 1274 and to out-couple a portion of the amplified radiation from the power amplifier to form the amplified light beam 1271.

The laser gas used in the discharge chambers of the master oscillator and the power amplifier can be any suitable gas for producing a laser beam around the required wavelengths and bandwidth. For example, the laser gas can be argon fluoride (ArF), which emits light at a wavelength of about 193 nm, or krypton fluoride (KrF), which emits light at a wavelength of about 248 nm.

In general, the light source 1270 can also include a control system 1278 in communication with the first stage 1272 and the second stage 1273. The control system 1278 includes one or more of digital electronic circuitry, computer hardware, firmware, and software. The control system 1278 includes memory, which can be read-only memory and/or random-access memory. Storage devices suitable for tangibly embodying computer program instructions and data include all forms of non-volatile memory, including, by way of example, semiconductor memory devices, such as EPROM, EEPROM, and flash memory devices; magnetic disks such as internal hard disks and removable disks; magneto-optical disks; and CD-ROM disks. The control system 1278 can also include one or more input devices (such as a keyboard, touch screen, microphone, mouse, hand-held input device, etc.) and one or more output devices (such as a speaker or a monitor).

The control system 1278 includes one or more programmable processors, and one or more computer program products tangibly embodied in a machine-readable storage device for execution by a programmable processor. The one or more programmable processors can each execute a program of instructions to perform desired functions by operating on input data and generating appropriate output. Generally, the processor receives instructions and data from memory. Any of the foregoing may be supplemented by, or incorporated in, specially designed ASICs (application-specific integrated circuits).

The control system 1278 includes a set of modules, with each module including a set of computer program products executed by one or more processors such as the processors. Moreover, any of the modules can access data stored within the memory. Each module can receive data from other components and then analyze such data as needed. Each module can be in communication with one or more other modules.

Although the control system 1278 is represented as a box (in which all of its components can be co-located), it is possible for the control system 1278 to be made up of components that are physically remote from each other. For example, a particular module can be physically co-located with the light source 1270 or a particular module can be physically co-located with the spectral feature adjuster 1275. Moreover, the control system 1278 can be a module incorporated into the control apparatus 128.

The first gas discharge stage 1272 can correspond to the gas discharge stage 108. The second gas discharge stage 1273 can correspond to the gas discharge stage 108. Or, each of the first gas discharge stage 1272 and the second gas discharge stage 1273 can correspond to the gas discharge stage 108. Thus, the apparatus 100, 700, or 900 described above can be designed to determine a position of a body in the first gas discharge stage 1272; to adjust a position of the body in the first gas discharge stage 1272; and to base the adjustment on the position on monitored performance parameters associated with the first gas discharge stage 1272. Additionally, or alternatively, the apparatus 100, 700, or 900 described above can be designed to determine a position of a body in the second gas discharge stage 1273; to adjust a position of the body in the second gas discharge stage 1273; and to base the adjustment on the position on monitored performance parameters associated with the second gas discharge stage 1273. The adjustment and optimization of the position of the body in the second gas discharge stage 1273 can be performed simultaneously with the adjustment and optimization of the position of the body in the first gas discharge stage 1272. Moreover, the performance parameters associated with the first gas discharge stage 1272 can be measured by measuring performance parameters of the seed light beam 1274 or of the amplified light beam 1271 (which is produced from the seed light beam 1273). The performance parameters associated with the second gas discharge stage 1273 can be measured by measuring performance parameters of the amplified light beam 1271.

If both the first gas discharge stage 1272 and the second gas discharge stage 1273 are under the control of the apparatus 100, 700, or 900, then a single control apparatus 128 can be configured to communicate with both sensor systems 124, both actuation systems 754, and both measurement systems 960.

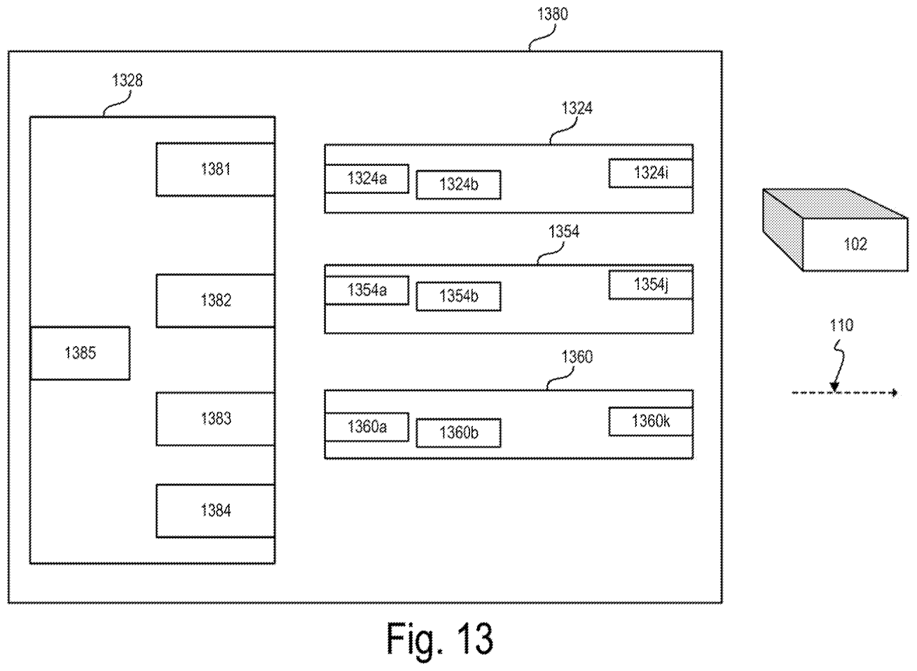

Referring to FIG. 13, a metrology kit 1380 includes the components that make up the apparatus (such as the apparatus 900). A metrology kit 1380 is useful because it does not need to be fixed or associated with a single gas discharge stage 108 and can be moved from one gas discharge stage 108 to another. Moreover, because of this, it is possible to use the metrology kit 1380 for more than one gas discharge stage 108 instead of setting up an apparatus 900 for each gas discharge stage 108, which is more costly.

The metrology kit 1380 includes a sensor system 1324 including a plurality of sensors 1324a, 1324b, . . . 1324i (where i is any integer greater than 1). Each sensor 1324a, 1324b, 1324i is configured to measure a physical aspect of a three-dimensional body 102 relative to that sensor. The metrology kit 1380 includes a measurement system 1360 including at least one measurement device 1360a, 1360b, . . . 1360j (where j is any integer). Each measurement device 1360a, 1360b, . . . 1360j is configured to measure a performance parameter of the light beam 110. The metrology kit 1380 includes an actuation system 1354 including a plurality of actuators 1354a, 1354b, . . . 1354k configured to physically couple to the body 102.

The metrology kit 1380 includes a control apparatus 1328 configured to be in communication with the sensor system 1324, the measurement system 1360, and the actuation system 1354. The control apparatus 1328 includes a sensor processing module 1381 configured to interface with the sensor system 1324 and receive sensor information from the sensor system 1324. The control apparatus 1328 includes a measurement processing module 1382 configured to interface with the measurement system 1360 and receive measurement information from the measurement system 1360. The control apparatus 1329 includes an actuator processing module 1383 configured to interface with the actuation system 1354.

The control apparatus 1328 can also include a light source processing module 1384 configured to interface with the gas discharge stage 108 having the three-dimensional body 102.

The control apparatus 1328 can also include an analysis processing module 1385 in communication with the sensor processing module 1381, the measurement processing module 1382, the actuator processing module 1383, and the light source processing module 1384. The analysis processing module 1385 is configured to, in use, instruct the light source processing module 1384 to adjust one or more characteristics of the gas discharge stage 108 and analyze the sensor information (from the sensor system 1324) and the measurement information (from the measurement system 1360) and determine an instruction to the actuator processing module 1383 based on the adjusted characteristics of the gas discharge stage 108.

The metrology kit 1380 is modular such that it is configured to be operably connected and disconnected from one or more gas discharge stages 108. Each gas discharge stage 108 includes a respective three-dimensional body 102 defining a cavity 112 that generates a respective light beam 110. Thus, when the position of the body 102 needs to be optimized, the metrology kit 1380 can be installed to the gas discharge chamber 108. For example, the sensors 1324a, 1324b, . . . 1324i can be mounted at respective locations relative to their respective region of the body 102. The measurement devices 1360a, 1360b, . . . 1360j can be placed at locations to measure the performance parameters of the light beam 110. The actuators 1354a, 1354b, . . . 1354k can be physically coupled to the respective regions of the body 102. And, the sensor system 1324, the measurement system 1360, and the actuation system 1354 can be connected to or placed in communication with the control apparatus 1328. After the body 102 has been optimized, the reverse steps for disconnection can be performed.

In some implementations, the measurement system 1360 includes, in place of one or more of the measurement devices, one or more measurement interfaces. Each measurement interface is able to be connected to a measurement device that is fixed within the gas discharge stage 108 and also to be connected to the control apparatus 128 in the kit 1380.

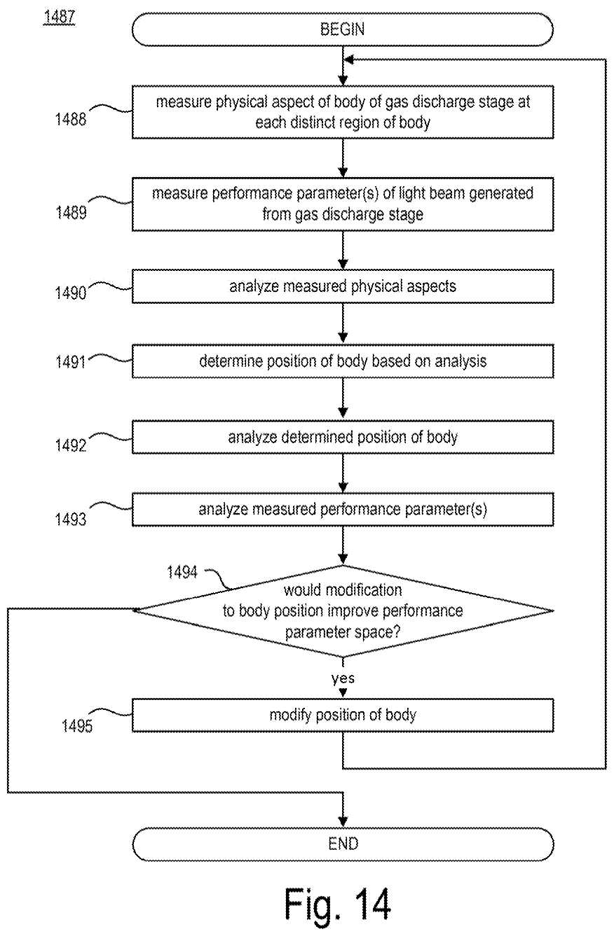

Referring to FIG. 14, a procedure 1487 is performed by the apparatus 900. The procedure 1487 can be performed any time a component of the gas discharge stage 108 is moved or replaced, or any time an efficiency of the gas discharge stage 108 drops below an acceptable range. The procedure 1487 is generally performed while the gas discharge stage 108 is offline from the lithography exposure apparatus.

The efficiency of the gas discharge stage 108 can be represented by one or more performance parameters of the light beam 110. Moreover, a set of plural performance parameters can be considered as the parameter space. The parameter space therefore includes a plurality of performance parameters. The procedure 1487 strives to optimize the parameter space. Optimization of the parameter space does not necessarily mean that a particular performance parameter is optimized or that each performance parameter is optimized. Rather, the set or plurality of performance parameters are determined that provide the most efficient operation of the gas discharge stage 108. As discussed above, examples of performance parameters include the energy E of the light beam 110, a spectral feature such as the bandwidth or the wavelength of the light beam 110, the dose of the light beam 110 at the apparatus (such as the lithography exposure apparatus), a repetition rate at which the pulses of the light beam 110 are produced, and a duty cycle of the light beam 110.

The procedure 1487 includes measuring, at each of the plurality of distinct regions 126a, 126b, etc. of the body 102 of the gas discharge stage 108, a physical aspect of the body 102 at that region (1488). For example, the sensor system 124 (and in particular, the sensors 124a, 124b, etc.) can measure the physical aspect at each distinct region 126a, 126b, etc.

The procedure 1487 includes measuring one or more performance parameters of the light beam 110 that is generated from the gas discharge stage 108 (1489). For example, the measurement system 960 can measure the one or more performance parameters of the light beam 110. It is possible for the measurement system 960 to measure only one performance parameter as a representation of the efficiency of the gas discharge stage 108. Moreover, it is also possible that the measurement system 960 measures a plurality of performance parameters in order to represent the efficiency of the gas discharge stage 108. Examples of performance parameters that can be measured include the repetition rate of the pulsed light beam 110, the energy of the pulsed light beam 110, the duty cycle of the pulsed light beam 110, and/or a spectral feature of the pulsed light beam 110.

The procedure 1487 includes analyzing the measured physical aspects (1490) to thereby determine a position of the body in the XYZ coordinate system 104 defined by the X axis 106 defined by the plurality of apertures determined by the optical components 140, 142 of the gas discharge stage 108 (1491). The procedure 1487 also includes analyzing the determined position of the body 102 of the gas discharge stage 108 (1492) and analyzing the one or more measured performance parameters (1493). The control apparatus 128 performs the analyses 1490, 1492, 1493 after receiving the outputs from the measurements 1488 and 1489 and after determining the position of the body 1491.

The procedure 1487 includes determining whether a modification to the position of the body 102 of the gas discharge stage 108 would improve one or more of the measured performance parameters (1494) and, if it is determined that the modification to the position of the body 102 of the gas discharge stage 108 would improve one or more of the measured performance parameters, then modifying the position of the body 102 of the gas discharge stage 108 (1495). For an example in which the performance parameter is the energy E of the light beam 110, the control apparatus 128 can use feedback control, such as what is shown in FIG. 11, and make incremental adjustments to the position of the body 102, then re-measure the performance parameter at 1489 to determine if that adjustment improved the performance parameter (1494).

If it is determined that no modification to the position of the body 102 would improve the one or more measured performance parameters (1494), then the procedure 1487 ends. In particular, the procedure 1487 has determined the position of the body 102 of the gas discharge stage 108 that optimizes the plurality of measured performance parameters. The optimal position of the body 102 of the gas discharge stage 108 provides an optimal set of values of the performance parameters of the light beam 110, and the procedure 1487 operates to modify the position of the body 102 of the gas discharge stage 108 to be at this optimal position.

The position of the body 102 of the gas discharge stage 108 can be modified (1495) based on the analysis of the determined position of the body 102 of the gas discharge stage 108 at 1492. The position of the body 102 of the gas discharge stage 108 can be determined (1491) by determining one or more of a translation of the body 102 of the gas discharge stage 108 from the X axis 106 and a rotation of the body 102 of the gas discharge stage 108 from the X axis 106. An example of this determination is described above with reference to FIG. 6.

As discussed above, the physical aspect of the body 102 at a distinct region of the body 102 can be measured (1488) by measuring a distance from the corresponding sensor to that region of the body 102.

The procedure 1487 can also include generating the light beam 110 from the gas discharge stage 108 by forming a resonator defined by a beam coupler (such as optical component 142) at one side of the body 102 and a beam turning device (such as optical component 140) at another side of the body 102, and generating energy within the gain medium in the cavity 112. The beam coupler and the beam turning device can also define the X axis 106.

As discussed above, and with reference to FIG. 15, the light beam 110 can be used in an apparatus such as a lithography exposure apparatus EX for patterning of a substrate W. In this case, the apparatus 100, 700, or 900 is incorporated into a light source LS that provides an amplified and pulsed light beam LB to the lithography exposure apparatus EX. The light beam LB can correspond to the light beam 110 output from the gas discharge stage 108. Or, the light beam LB can correspond to a light beam that is formed from the light beam 110 output from the gas discharge stage 108. Moreover, as discussed above, the gas discharge stage 108 and the apparatus 100, 700, or 900 can be incorporated into a dual-stage light source LS.

For example, although connections between the control apparatus 128 and other components of the apparatuses 100, 700, 900 are shown as lines, the connections between the control apparatus 128 and the other components can be wired connections or wireless connections.

The implementations may further be described using the following clauses:

1. A light source apparatus comprising:

a gas discharge stage including a three-dimensional body defining a cavity that is configured to interact with an energy source, the body including at least two ports that are transmissive to a light beam having a wavelength in the ultraviolet range;

a sensor system comprising a plurality of sensors, each sensor is configured to measure a physical aspect of a respective distinct region of the body of the gas discharge stage relative to that sensor; and

a control apparatus in communication with the sensor system, and configured to analyze the measured physical aspects from the sensors to thereby determine a position of the body of the gas discharge stage in an XYZ coordinate system defined by an X axis, wherein the X axis is defined by the geometry of the gas discharge stage.

2. The light source apparatus of clause 1, further comprising a measurement system configured to measure one or more performance parameters of a light beam that is generated from the gas discharge stage.

3. The light source apparatus of clause 2, wherein the control apparatus is in communication with the measurement system, and is further configured to:

analyze both the position of the body of the gas discharge stage in the XYZ coordinate system and the one or more measured performance parameters of the light beam; and

determine whether a modification to the position of the body of the gas discharge stage would improve one or more of the measured performance parameters.

4. The light source apparatus of clause 3, further comprising an actuation system physically coupled to the body of the gas discharge stage, and configured to adjust a position of the body of the gas discharge stage.

5. The light source apparatus of clause 4, wherein the control apparatus is in communication with the actuation system and is configured to provide a signal to the actuation system based on the determination regarding whether the position of the body of the gas discharge stage should be modified.

6. The light source apparatus of clause 5, wherein the actuation system includes a plurality of actuators, each actuator configured to be in physical communication with a region of the body of the gas discharge stage.

7. The light source apparatus of clause 6, wherein each actuator includes one or more of an electro-mechanical device, a servomechanism, an electrical servomechanism, a hydraulic servomechanism, and/or a pneumatic servomechanism.

8. The light source apparatus of clause 1, wherein the control apparatus is configured to determine the position of the body of the gas discharge stage in the XYZ coordinate system by determining a translation of the body of the gas discharge stage from the X axis or a rotation of the body of the gas discharge stage from the X axis.

9. The light source apparatus of clause 8, wherein the translation of the body of the gas discharge stage from the X axis includes one or more of a translation of the body of the gas discharge stage along the X axis, a translation of the body of the gas discharge stage along a Y axis that is perpendicular with the X axis, and/or a translation of the body of the gas discharge stage along a Z axis that is perpendicular with the X axis and the Y axis.

10. The light source apparatus of clause 8, wherein the rotation of the body of the gas discharge stage from the X axis includes one or more of a rotation of the body of the gas discharge stage about the X axis, a rotation of the body of the gas discharge stage about a Y axis that is perpendicular with the X axis, and/or a rotation of the body of the gas discharge stage along a Z axis that is perpendicular with the X axis and the Y axis.

11. The light source apparatus of clause 1, wherein each sensor is configured to measure as the physical aspect of the body of the gas discharge stage relative to that sensor a distance from the sensor to the body of the gas discharge stage.

12. The light source apparatus of clause 1, wherein the gas discharge stage includes a beam turning device at a first end of the body and a beam coupler at a second end of the body, the beam turning device and the beam coupler intersecting the X axis such that a light beam produced in the gas discharge stage interacts with the beam coupler and the beam turning device.

13. The light source apparatus of clause 12, wherein, when the body of the gas discharge stage is within a range of acceptable positions, the energy source supplies energy to the cavity of the body, and the beam tuning device and beam coupler are aligned, the light beam is generated.

14. The light source apparatus of clause 13, wherein the light beam is an amplified light beam having a wavelength in the ultraviolet range.

15. The light source apparatus of clause 12, wherein the beam turning device is an optical module that includes a plurality of optics for selecting and adjusting a wavelength of the light beam and the beam coupler includes a partially reflecting mirror.

16. The light source apparatus of clause 12, wherein the beam turning device includes an arrangement of optics that is configured to receive the light beam exiting the body of the gas discharge stage through a first port and changing a direction of the light beam so that the light beam re-enters the body of the gas discharge stage through the first port.

17. The light source apparatus of clause 12, wherein the gas discharge stage also includes a beam expander configured to interact with the light beam as it travels between the beam coupler and the cavity.

18. The light source apparatus of clause 1, wherein each sensor is configured to be fixedly mounted relative to the body of the gas discharge stage.

19. The light source apparatus of clause 18, wherein each sensor is configured to be fixed at a distance from the other sensor when it is fixedly mounted relative to the body of the gas discharge stage.

20. The light source apparatus of clause 1, further comprising:

a second gas discharge stage that is optically in series with the gas discharge stage, the second gas discharge stage having a second three-dimensional body defining a second cavity that is configured to interact with an energy source, the second body including at least two ports that are transmissive to a light beam having a wavelength in the ultraviolet range; and

a second plurality of sensors, each sensor in the second plurality configured to measure a physical aspect of a respective distinct region of the second body relative to that sensor;

wherein the control apparatus is in communication with the second plurality of sensors, and configured to analyze the measured physical aspects from the sensors of the second plurality to thereby determine a position of the second body relative to a second XYZ coordinate system defined by a second X axis that passes through the at least two ports of the second body.

21. The light source apparatus of clause 1, wherein each sensor includes a displacement sensor.

22. The light source apparatus of clause 21, wherein a displacement sensor is an optical displacement sensor, a linear proximity sensor, an electromagnetic sensor, or an ultrasonic displacement sensor.

23. The light source apparatus of clause 1, wherein each sensor includes a contact-less sensor.

24. The light source apparatus of clause 1, wherein the X axis is defined by a beam turning device at a first end of the body and optically coupled with a first port and a beam coupler at a second end of the body and optically coupled with a second port.

25. A metrology apparatus comprising:

a sensor system including a plurality of sensors, each sensor is configured to measure a physical aspect of a body of a gas discharge stage relative to that sensor;

a measurement system configured to measure one or more performance parameters of a light beam that is generated from the gas discharge stage;

an actuation system including a plurality of actuators, each actuator configured to be physically coupled to a distinct region of the body of the gas discharge stage, the plurality of actuators working together to adjust a position of the body of the gas discharge stage; and

a control apparatus in communication with the sensor system, the measurement system, and the actuation system, and configured to:
analyze the measured physical aspects from the sensors to thereby determine a position of the body of the gas discharge stage in an XYZ coordinate system defined by an X axis that is defined by the gas discharge stage;
analyze the position of the body of the gas discharge stage;
analyze the one or more measured performance parameters; and
provide a signal to the actuation system to modify the position of the body of the gas discharge stage based on the analyses of the position of the body of the gas discharge stage and the one or more measured performance parameters.

26. The metrology apparatus of clause 25, wherein the sensors are positioned apart from each other and relative to the body of the gas discharge stage.

27. The metrology apparatus of clause 25, wherein the control apparatus is configured to provide the signal to the actuation system to modify the position of the body of the gas discharge stage based on the analyses of the position of the body of the gas discharge stage and the one or more measured performance parameters by determining a position of the body of the gas discharge stage that optimizes a plurality of the performance parameters of the light beam.

28. The metrology apparatus of clause 25, wherein the X axis is defined by a beam turning device at a first end of the body and optically coupled with a first port and a beam coupler at a second end of the body and optically coupled with a second port.

29. A method comprising:

measuring, at each of a plurality of distinct regions of a body of a gas discharge stage of a light source, a physical aspect of the body at that region;

measuring one or more performance parameters of a light beam that is generated from the gas discharge stage;

analyzing the measured physical aspects to thereby determine a position of the body in an XYZ coordinate system defined by an X axis, wherein the X axis is defined by a plurality of apertures associated with the gas discharge stage;

analyzing the determined position of the body of the gas discharge stage;

analyzing the one or more measured performance parameters;

determining whether a modification to the position of the body of the gas discharge stage would improve one or more of the measured performance parameters; and

if it is determined that a modification to the position of the body of the gas discharge stage would improve one or more of the measured performance parameters, then modifying the position of the body of the gas discharge stage.

30. The method of clause 29, wherein modifying the position of the body of the gas discharge stage is based on the analysis of the determined position of the body of the gas discharge stage.

31. The method of clause 29, wherein determining the position of the body of the gas discharge stage includes determining one or more of a translation of the body of the gas discharge stage from the X axis and a rotation of the body of the gas discharge stage from the X axis.

32. The method of clause 31, wherein translating the body of the gas discharge stage from the X axis includes one or more of translating the body of the gas discharge stage along the X axis, translating the body of the gas discharge stage along a Y axis that is perpendicular with the X axis, and translating the body of the gas discharge stage along a Z axis that is perpendicular with the X axis and the Y axis.

33. The method of clause 31, wherein rotating the body of the gas discharge stage from the X axis includes one or more of rotating the body of the gas discharge stage about the X axis, rotating the body of the gas discharge stage about a Y axis that is perpendicular with the X axis, and/or rotating the body of the gas discharge stage along a Z axis that is perpendicular with the X axis and the Y axis.

34. The method of clause 29, wherein measuring a physical aspect of the body at that region comprises measuring a distance from the sensor to the region of the body of the gas discharge stage.

35. The method of clause 29, wherein determining whether the modification to the position of the body of the gas discharge stage would improve one or more of the measured performance parameters comprises determining a position of the body of the gas discharge stage that optimizes a plurality of measured performance parameters.

36. The method of clause 29, further comprising generating the light beam from the gas discharge stage including forming a resonator defined by a beam coupler at one side of the body and a beam turning device at another side of the body, the beam coupler and the beam turning device defining the X axis and generating energy within a gain medium in a cavity defined by the body.

37. The method of clause 29, wherein measuring one or more performance parameters of the light beam comprises measuring a plurality of performance parameters.

38. The method of clause 37, wherein measuring the plurality of performance parameters comprises measuring two or more of a repetition rate of a pulsed light beam produced by the light source, an energy of the pulsed light beam, a duty cycle of the pulsed light beam, and/or a spectral feature of the pulsed light beam.

39. The method of clause 37, further comprising:

determining an optimal position of the body of the gas discharge stage that provides an optimal set of values of the performance parameters of the light beam; and

modifying the position of the body of the gas discharge stage to be at the optimal position.

40. A metrology kit comprising:

a sensor system including a plurality of sensors, each sensor is configured to measure a physical aspect of a three-dimensional body relative to that sensor;

a measurement system including a plurality of measurement devices, each measurement device configured to measure a performance parameter of a light beam;

an actuation system including a plurality of actuators configured to physically couple to the three-dimensional body; and

a control apparatus configured to be in communication with the sensor system, the measurement system, and the actuation system, the control apparatus including:
a sensor processing module configured to interface with the sensor system and receive sensor information from the sensor system;
a measurement processing module configured to interface with the measurement system and receive measurement information from the measurement system;
an actuator processing module configured to interface with the actuation system; and
a light source processing module configured to interface with a gas discharge stage having a three-dimensional body.

41. The metrology kit of clause 40, wherein the control apparatus includes an analysis processing module in communication with the sensor processing module, the measurement processing module, the actuator processing module, and the light source processing module, and configured to, in use, instruct the light source processing module to adjust one or more characteristics of the gas discharge stage and analyze the sensor information and the measurement information and determine an instruction to the actuator processing module based on the adjusted characteristics of the gas discharge stage.

42. The metrology kit of clause 40, wherein the metrology kit is modular such that it is configured to be operably connected and disconnected from one or more gas discharge stages, each gas discharge stage including a respective three-dimensional body defining a cavity that generates a respective light beam.

Other implementations are within the scope of the following claims.

What is claimed is:

1. A light source apparatus comprising:
a gas discharge stage including a three-dimensional body defining a cavity that is configured to interact with an energy source, the body including at least two ports that are transmissive to a light beam having a wavelength in the ultraviolet range;
a sensor system comprising a plurality of sensors, each sensor is configured to measure a physical aspect of a respective distinct region of the body of the gas discharge stage relative to that sensor; and
a control apparatus in communication with the sensor system, and configured to analyze the measured physical aspects from the sensors to thereby determine a position of the body of the gas discharge stage in an XYZ coordinate system defined by an X axis, wherein the X axis is defined by the geometry of the gas discharge stage.

2. The light source apparatus of claim 1, further comprising a measurement system configured to measure one or more performance parameters of a light beam that is generated from the gas discharge stage;
wherein the control apparatus is in communication with the measurement system, and is further configured to:
analyze both the position of the body of the gas discharge stage in the XYZ coordinate system and the one or more measured performance parameters of the light beam; and
determine whether a modification to the position of the body of the gas discharge stage would improve one or more of the measured performance parameters.

3. The light source apparatus of claim 2, further comprising an actuation system physically coupled to the body of the gas discharge stage, and configured to adjust a position of the body of the gas discharge stage;
wherein the control apparatus is in communication with the actuation system and is configured to provide a signal to the actuation system based on the determination regarding whether the position of the body of the gas discharge stage should be modified.

4. The light source apparatus of claim 3, wherein the actuation system includes a plurality of actuators, each actuator configured to be in physical communication with a region of the body of the gas discharge stage.

5. The light source apparatus of claim 1, wherein the control apparatus is configured to determine the position of the body of the gas discharge stage in the XYZ coordinate system by determining one or more of a translation of the body of the gas discharge stage from the X axis and/or a rotation of the body of the gas discharge stage from the X axis.

6. The light source apparatus of claim 5, wherein:
the translation of the body of the gas discharge stage from the X axis includes one or more of a translation of the body of the gas discharge stage along the X axis, a translation of the body of the gas discharge stage along a Y axis that is perpendicular with the X axis, and/or a translation of the body of the gas discharge stage along a Z axis that is perpendicular with the X axis and the Y axis; and
the rotation of the body of the gas discharge stage from the X axis includes one or more of a rotation of the body of the gas discharge stage about the X axis, a rotation of the body of the gas discharge stage about a Y axis that is perpendicular with the X axis, and/or a rotation of the body of the gas discharge stage along a Z axis that is perpendicular with the X axis and the Y axis.

7. The light source apparatus of claim 1, wherein each sensor is configured to measure as the physical aspect of the body of the gas discharge stage relative to that sensor a distance from the sensor to the body of the gas discharge stage.

8. The light source apparatus of claim 1, wherein:
the gas discharge stage includes a beam turning device at a first end of the body and a beam coupler at a second end of the body, the beam turning device and the beam coupler intersecting the X axis such that a light beam produced in the gas discharge stage interacts with the beam coupler and the beam turning device; and
when the body of the gas discharge stage is within a range of acceptable positions, the energy source supplies energy to the cavity of the body, and the beam tuning device and beam coupler are aligned, the light beam is generated.

9. The light source apparatus of claim 8, wherein the light beam is an amplified light beam having a wavelength in the ultraviolet range.

10. The light source apparatus of claim 8, wherein:
the beam turning device is an optical module that includes a plurality of optics for selecting and adjusting a wavelength of the light beam and the beam coupler includes a partially reflecting mirror; and/or
the beam turning device includes an arrangement of optics that is configured to receive the light beam exiting the body of the gas discharge stage through a first port and changing a direction of the light beam so that the light beam re-enters the body of the gas discharge stage through the first port.

11. The light source apparatus of claim 1, wherein each sensor is configured to be fixedly mounted relative to the body of the gas discharge stage, and each sensor is configured to be fixed at a distance from the other sensor when it is fixedly mounted relative to the body of the gas discharge stage.

12. The light source apparatus of claim 1, further comprising:
a second gas discharge stage that is optically in series with the gas discharge stage, the second gas discharge stage having a second three-dimensional body defining a second cavity that is configured to interact with an energy source, the second body including at least two ports that are transmissive to a light beam having a wavelength in the ultraviolet range; and
a second plurality of sensors, each sensor in the second plurality configured to measure a physical aspect of a respective distinct region of the second body relative to that sensor;
wherein the control apparatus is in communication with the second plurality of sensors, and configured to analyze the measured physical aspects from the sensors of the second plurality to thereby determine a position of the second body relative to a second XYZ coordinate system defined by a second X axis that passes through the at least two ports of the second body.

13. The light source apparatus of claim 1, wherein each sensor includes a contact-less sensor.

14. The light source apparatus of claim 1, wherein the X axis is defined by a beam turning device at a first end of the body and optically coupled with a first port and a beam coupler at a second end of the body and optically coupled with a second port.

15. A metrology apparatus comprising:
a sensor system including a plurality of sensors, each sensor is configured to measure a physical aspect of a body of a gas discharge stage relative to that sensor;
a measurement system configured to measure one or more performance parameters of a light beam that is generated from the gas discharge stage;
an actuation system including a plurality of actuators, each actuator configured to be physically coupled to a distinct region of the body of the gas discharge stage, the plurality of actuators working together to adjust a position of the body of the gas discharge stage; and
a control apparatus in communication with the sensor system, the measurement system, and the actuation system, and configured to:
analyze the measured physical aspects from the sensors to thereby determine a position of the body of the gas discharge stage in an XYZ coordinate system defined by an X axis that is defined by the gas discharge stage;
analyze the position of the body of the gas discharge stage;
analyze the one or more measured performance parameters; and
provide a signal to the actuation system to modify the position of the body of the gas discharge stage based on the analyses of the position of the body of the gas discharge stage and the one or more measured performance parameters.

16. The metrology apparatus of claim 15, wherein the sensors are positioned apart from each other and relative to the body of the gas discharge stage.

17. The metrology apparatus of claim 15, wherein the control apparatus is configured to provide the signal to the actuation system to modify the position of the body of the gas discharge stage based on the analyses of the position of the body of the gas discharge stage and the one or more measured performance parameters by determining a position of the body of the gas discharge stage that optimizes a plurality of the performance parameters of the light beam.

18. The metrology apparatus of claim 15, wherein the X axis is defined by a beam turning device at a first end of the body and optically coupled with a first port and a beam coupler at a second end of the body and optically coupled with a second port.

19. A method comprising:
measuring, at each of a plurality of distinct regions of a body of a gas discharge stage of a light source, a physical aspect of the body at that region;
measuring one or more performance parameters of a light beam that is generated from the gas discharge stage;
analyzing the measured physical aspects to thereby determine a position of the body in an XYZ coordinate system defined by an X axis, wherein the X axis is defined by a plurality of apertures associated with the gas discharge stage;
analyzing the determined position of the body of the gas discharge stage;
analyzing the one or more measured performance parameters;
determining whether a modification to the position of the body of the gas discharge stage would improve one or more of the measured performance parameters; and
if it is determined that a modification to the position of the body of the gas discharge stage would improve one or more of the measured performance parameters, then modifying the position of the body of the gas discharge stage.

20. The method of claim 19, wherein modifying the position of the body of the gas discharge stage is based on the analysis of the determined position of the body of the gas discharge stage.

21. The method of claim 19, wherein:
determining the position of the body of the gas discharge stage includes determining one or more of a translation of the body of the gas discharge stage from the X axis and/or a rotation of the body of the gas discharge stage from the X axis;
translating the body of the gas discharge stage from the X axis includes one or more of translating the body of the gas discharge stage along the X axis, translating the body of the gas discharge stage along a Y axis that is perpendicular with the X axis, and/or translating the body of the gas discharge stage along a Z axis that is perpendicular with the X axis and the Y axis; and
rotating the body of the gas discharge stage from the X axis includes one or more of rotating the body of the gas discharge stage about the X axis, rotating the body of the gas discharge stage about a Y axis that is perpendicular with the X axis, and/or rotating the body of the gas discharge stage along a Z axis that is perpendicular with the X axis and the Y axis.

22. The method of claim 19, wherein measuring a physical aspect of the body at that region comprises measuring a distance from the sensor to the region of the body of the gas discharge stage.

23. The method of claim 19, wherein determining whether the modification to the position of the body of the gas discharge stage would improve one or more of the measured performance parameters comprises determining a position of the body of the gas discharge stage that optimizes a plurality of measured performance parameters.

24. The method of claim 19, further comprising:
determining an optimal position of the body of the gas discharge stage that provides an optimal set of values of one or more performance parameters of the light beam; and
modifying the position of the body of the gas discharge stage to be at the optimal position.

25. A metrology kit comprising:
a sensor system including a plurality of sensors, each sensor is configured to measure a physical aspect of a three-dimensional body relative to that sensor;
a measurement system including a plurality of measurement devices, each measurement device configured to measure a performance parameter of a light beam;
an actuation system including a plurality of actuators configured to physically couple to the three-dimensional body; and
a control apparatus configured to be in communication with the sensor system, the measurement system, and the actuation system, the control apparatus including:
a sensor processing module configured to interface with the sensor system and receive sensor information from the sensor system;
a measurement processing module configured to interface with the measurement system and receive measurement information from the measurement system;
an actuator processing module configured to interface with the actuation system; and
a light source processing module configured to interface with a gas discharge stage having a three-dimensional body.
